(19) United States
(12) Patent Application Publication
(10) Pub. No.: US 2003/0016499 A1
(43) Pub. Date: Jan. 23, 2003

(54) Heat collector

(76) Inventors: Masaaki Tanaka, Nagoya-city (JP); Kenichi Fujiwara, Matsumoto-city (JP); Hideaki Sato, Anjo-city (JP); Mitsuharu Inagaki, Kariya-city (JP)

Correspondence Address: HARNESS, DICKEY & PIERCE, P.L.C., P.O. BOX 828, BLOOMFIELD HILLS, MI, 48303, US

(21) Appl. No.: 10/195,579

(22) Filed: Jul. 15, 2002

(30) Foreign Application Priority Data
Jul. 19, 2001 (JP) 2001-220176
Feb. 19, 2002 (JP) 2002-41477

(51) Int. Cl. H05K 7/20

(52) U.S. Cl. 361/700; 62/259.2; 165/104.33

(57) ABSTRACT

Repairing or replacing a heat-generating instrument in a heat collector entails providing an electromagnetic valve on an upstream side of a fluid passage for supplying fluid pressure to a heat-collecting diaphragm (101). The heat collector has

a heat-collecting diaphragm (101) for deforming upon receipt of a fluid pressure to contact a radiating surface of the heat-generating instrument, a heat collector casing fixing the heat-collecting diaphragm thereon for defining a pressure chamber to apply the fluid pressure to the heat-collecting diaphragm and a valve device provided on a fluid inlet side of the pressure chamber for opening and closing a fluid passage. The heat collector can be detached from a heat-generating instrument without draining a heat medium out of the heat collector. The heat collector is applicable to a cooling system for cooling electric apparatuses inside, say, a cellular phone base station.

### CROSS REFERENCE TO RELATED APPLICATION

This application is based upon, claims the benefit of priority of, and incorporates by reference the contents of prior Japanese Patent Applications No. 2001-220176 filed Jul. 19, 2001, and No. 2002-41477 filed Feb. 19, 2002.

### BACKGROUND OF THE INVENTION

1. Technical Field of the Invention

The present invention relates to a heat collector for collecting heat of a heat-generating instrument, the heat collector being effective for use in a cooling system for cooling an electronic instrument or the like inside a cellular phone base station.

2. Description of Related Art

Generally, a heat collector for collecting heat of a heat-generating instrument such as an electronic instrument is disclosed in Japanese Patent Laid-Open Publication No. Sho. 63-283048, for example. This disclosure reveals an accordion-type bellows made of a thin plate disposed in a position opposite to a radiating surface of a heat-generating instrument. Cooling water is filled and circulated inside the bellows to collect heat out of the heat-generating instrument, and the bellows is pressed against a heat-generating element with fluid pressure of the cooling water.

A heat collector needs to be detached from a heat-generating instrument in the event of repairing or replacing the heat-generating instrument. However, regarding the heat collector designed to deform and expand a movable member such as the bellows by fluid pressure as the invention disclosed in the above-mentioned publication, it is necessary to drain the fluid out of the heat collector in the event of detaching the heat collector from the heat-generating instrument. Accordingly, there is a problem that an operation of detaching the heat collector from the heat-generating instrument, that is, an operation of repairing or replacing the heat-generating instrument is complicated and workability is therefore reduced. Also, since the bellows do not contract in the horizontal direction, the bellows conform to a shape that makes it very difficult to detach a heating element. Such a problem will be hereinafter referred to as a first problem.

Moreover, according to the invention disclosed in the above-mentioned publication, a pump is required for generating sufficient fluid pressure to deform and expand the bellows. Therefore, there is a problem that reduction in manufacturing costs is difficult to achieve. Such a problem will be hereinafter referred to as a second problem.

Furthermore, it is difficult to achieve complete close contact (no spaces) between the bellows and the heat-generating instrument solely by use of the fluid pressure inside the bellows. Accordingly, there is a problem that enhancement of heat-collecting capability is difficult. Such a problem will be hereinafter referred to as a third problem.

### SUMMARY OF THE INVENTION

In consideration of the above problems, it is an object of the present invention to solve at least one problem out of the foregoing first to third problems, or to enhance the heat-collecting capability of a heat collector.

To attain the foregoing object, embodiments of the invention encompass a heat collector for collecting heat of a heat-generating instrument, which includes a heat-collecting diaphragm for being deformed upon receipt of fluid pressure to contact with a radiating surface of the heat-generating instrument. Additionally, there is a heat collector casing fixing the heat-collecting diaphragm thereon for constituting a pressure chamber to apply fluid pressure to the heat-collecting diaphragm, and a valve device provided on a fluid inlet side of the pressure chamber for opening and closing a fluid passage.

In this way, in the event of repairing or replacing the heat-generating instrument, supply of the fluid to the pressure chamber stops if the valve device closes. Accordingly, the fluid pressure acting on the heat-collecting diaphragm disappears and the heat-collecting diaphragm disengages from the radiating surface.

Accordingly, it is possible to detach the heat collector from the heat-generating instrument without draining the fluid out of the heat collector. Therefore, it is possible to enhance workability of repairing or replacing the heat-generating instrument.

The valve device may be designed to close the fluid passage when a heat value of the heat-generating instrument falls from a predetermined value. In this way, it is possible to minimize leakage of the fluid and to start an operation for repairing or replacing the heat-generating instrument immediately without carrying out a switching operation for closing the valve device when the heat-generating instrument is repaired or replaced. Accordingly, it is possible to enhance workability of repairing or replacing the heat-generating instrument.

Alternatively, the valve device may be designed to close the fluid passage when the fluid pressure falls from a predetermined pressure value. In this way, it is possible to minimize leakage of the fluid and to start an operation for repairing or replacing the heat-generating instrument immediately without carrying out a switching operation for closing the valve device when the heat-generating instrument is repaired or replaced. Accordingly, it is possible to enhance workability of repairing or replacing the heat-generating instrument.

The valve device may be designed to close the fluid passage when an electric signal of the heat-generating instrument is not present. In this way, it is possible to minimize leakage of the fluid and to start an operation for repairing or replacing the heat-generating instrument immediately without carrying out a switching operation for closing the valve device (104) when the heat-generating instrument (120) is repaired or replaced. Accordingly, it is possible to enhance workability of repairing or replacing the heat-generating instrument.

Furthermore, a pump device for supplying the fluid to the pressure chamber is designed to stop operating when pressure inside the pressure chamber falls from a predetermined pressure value. In this way, it is possible to minimize leakage of the fluid and to start an operation for repairing or replacing the heat-generating instrument immediately without carrying out a switching operation for stopping the pump device when the heat-generating instrument is repaired or replaced. Accordingly, it is possible to enhance workability of repairing or replacing the heat-generating instrument. Moreover, the pump device for supplying the fluid to the pressure chamber may be designed to stop operating when a heat value of the heat-generating instrument falls from a predetermined value.

In this way, it is possible to minimize leakage of the fluid and to start an operation for repairing or replacing the heat-generating instrument immediately without carrying out a switching operation for stopping the pump device when the heat-generating instrument is repaired or replaced.

Alternatively, the pump device for supplying the fluid to the pressure chamber is designed to stop operating when an electric signal of the heat-generating instrument is not present. In this way, it is possible to minimize leakage of the fluid and to start an operation for repairing or replacing the heat-generating instrument immediately without carrying out a switching operation for stopping the pump device when the heat-generating instrument is repaired or replaced.

Continuing with the description of the invention, a heat collector is present for collecting heat dissipated by a heat-generating instrument, which includes a heat-radiating diaphragm for enclosing a pressure chamber of which an inner pressure varies upon receipt of heat from the heat-generating instrument and for being deformed in accordance with pressure inside the pressure chamber. Also present is a heat-collecting plate for contacting the heat-radiating diaphragm when the heat-radiating diaphragm is deformed by an increase in the pressure inside the pressure chamber.

As described above, according to the present invention, it is possible to deform the heat-collecting diaphragm by use of the heat generated by the heat-generating instrument. Therefore, it is possible to reduce pumping work of the pump for pumping the fluid by pressure or to reduce ejection pressure of the pump. Consequently, it is possible to adopt a pump with relatively small ejection pressure. Therefore, it is possible to reduce manufacturing costs of the heat collector.

According to another aspect of the invention, a valve device is provided for opening and closing a fluid passage to effectuate circulation of fluid for retrieving heat collected on a heat-collecting plate. In this way, it is possible to detach the heat collector from the heat-generating instrument without draining the fluid out of the heat collector as similar to an aspect of the invention described above. Therefore, it is possible to enhance workability of repairing or replacing the heat-generating instrument.

In another aspect of the invention, the valve device is designed to close the fluid passage when fluid pressure falls from a predetermined pressure value. In this way, it is possible to minimize leakage of the fluid and to start an operation for repairing or replacing the heat-generating instrument immediately without carrying out a switching operation for closing the valve device when the heat-generating instrument is repaired or replaced. Accordingly, it is possible to enhance workability of repairing or replacing the heat-generating instrument.

In anther aspect of the invention, a pump device is provided in order to circulate the fluid for retrieving the heat collected on the heat-collecting plate, and the pump device is designed to stop operating when the fluid pressure falls from a predetermined pressure value. In this way, it is possible to minimize leakage of the fluid and to start an operation for repairing or replacing the heat-generating instrument immediately without carrying out a switching operation for stopping the pump device when the heat-generating instrument is repaired or replaced. Accordingly, it is possible to enhance workability of repairing or replacing the heat-generating instrument.

In anther aspect of the invention, a pump device is provided in order to circulate the fluid for retrieving the heat collected on the heat-collecting plate, and the pump device is designed to stop operating when a heat value of the heat-generating instrument falls from a predetermined value. In this way, it is possible to minimize leakage of the fluid and to start an operation for repairing or replacing the heat-generating instrument immediately without carrying out a switching operation for stopping the pump device when the heat-generating instrument is repaired or replaced. Accordingly, it is possible to enhance workability of repairing or replacing the heat-generating instrument.

In another aspect of the invention, a heat collector collects heat from a heat-generating instrument by allowing a diaphragm deformable in accordance with inner pressure to contact a heat-transferring surface. In this case, an enclosed space is provided outside the diaphragm, and the heat-transferring surface and the diaphragm are allowed to closely contact each other by reducing pressure inside the enclosed space.

In this way, it is possible to allow the diaphragm to closely contact the heat-transferring surface by low inner pressure. Accordingly, it is possible to reduce contact thermal resistance between the diaphragm and the heat-transferring surface.

In another aspect of the invention, fluid having thermal conductivity at least higher than air is filled into the enclosed space after the pressure inside the enclosed space is lowered. In this way, it is possible to reduce contact thermal resistance between the diaphragm and the heat-transferring surface.

In another aspect of the invention, a cooling system for cooling a heat-generating instrument composed of a plurality of heat-generating elements, which includes heat collectors being provided in a number corresponding to the heat-generating elements for collecting heat of the heat-generating elements, and cooling means for retrieving and cooling down the heat collected in the heat collectors. In this way, it is possible to detach the heat collector corresponding to the heat-generating element subject to repair or replacement.

In another aspect of the invention, a base member is provided with positioning means for positioning the heat-generating instrument and the heat collector. In this way, upon refitting the heat-generating instrument to the heat collector after the heat-generating instrument is detached from the heat collector, for example, it is possible to control a dimension of a gap between the heat-generating instrument and the heat collector easily and accurately. Therefore, it is possible to facilitate an operation of repairing or replacing the heat-generating instrument. Moreover, since it is possible to control the gap dimension accurately, it is possible to control a degree of close contact (pressure on a contact surface) of the diaphragm accurately, whereby substantial reduction in heat-collecting capability is avoidable upon an operation of repairing or replacing the heat-generating instrument.

In another aspect of the invention, a heat collector, for collecting heat of a heat-generating instrument, includes a heat-collecting diaphragm for contacting a radiating surface of the heat-generating instrument upon receipt of fluid pressure, and a heat collector internal structure being provided with a protrusion, which is disposed opposite to the heat-collecting diaphragm in a position opposite to the radiating surface. The heat-collecting diaphragm is interposed between the structure and the radiating surface. In this way, the protrusion functions as a turbulence promoter to disturb a fluid flow, whereby thermal conductivity between the fluid and the heat-collecting diaphragm is increased. Therefore, thermal transfer from the radiating surface to the heat-collecting diaphragm is promoted, whereby the heat-generating instrument can be cooled down.

In another aspect of the invention, the heat-collecting diaphragm is formed of a thin film. In this way, the heat-collecting diaphragm can be easily bent and deformed. Accordingly, the heat-collecting diaphragm is adapted to the radiating surface in a close contacting manner when the heat-collecting diaphragm contacts with the radiating surface upon receipt of the fluid pressure. Consequently, it is possible to reduce contact thermal resistance between the radiating surface and the heat-collecting diaphragm, whereby thermal transfer from the radiating surface to the heat-collecting diaphragm is promoted. Accordingly, it is possible to cool down the heat-generating instrument.

If a gap dimension (Δ1) between the heat-collecting diaphragm and a tip of the protrusion is set 1 mm or less as defined in yet another aspect of the invention, then it is possible to increase a flow rate of a heat medium flowing through the gap between the heat-collecting diaphragm and the tip of the protrusion. Accordingly, it is possible to increase thermal conductivity between the heat-collecting diaphragm and the heat medium.

In another aspect, the multiple protrusions are provided at given intervals in a circulating direction of the fluid, and an outside dimension (L1) in a region of the protrusion being approximately parallel to the circulating direction of the fluid is smaller than an outside dimension (L2) in a region of the heat-generating element being approximately parallel to the circulating direction of the fluid.

In this way, it is possible to permit a reverse flow, which is reflected by the protrusion so as to collide against the protrusion on an upstream side and thereby deflect a circulating direction thereof so as to collide against a region of the heat-collecting diaphragm corresponding to the heat-generating elements. Accordingly, it is possible to dissipate the heat of the heat-generating element more reliably from the radiating surface toward the heat-collecting diaphragm.

In another aspect of the invention, an end portion of the heat-generating element on a downstream side of a fluid flow is located at a more downstream side than an end portion of the protrusion on the downstream side of the fluid flow when the protrusion and the heat-generating element are viewed from the protrusion side. In this way, it is surely possible to allow the reverse flow to collide against the region of the heat-collecting diaphragm corresponding to the heat-generating element. Accordingly, it is possible to dissipate the heat of the heat-generating element more reliably from the radiating surface toward the heat-collecting diaphragm. Additionally, the fluid may be designed to flow intensively in a region corresponding to the heat-generating element. In this way, it is possible to cool down the heat-generating element.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

FIG. 1 is a schematic diagram of a cooling system according to an embodiment of the present invention;

FIG. 2A is a perspective view showing a heat collector, a heat-generating instrument, and a heat-generating element according to a first embodiment of the present invention;

FIG. 2B is a cross-sectional view showing the state of fitting the heat collector to the heat-generating instrument;

FIG. 3 is a schematic diagram showing a flow of a heat medium in a first basic operating mode according to the first embodiment of the present invention;

FIG. 4 is a schematic diagram showing a flow of the heat medium in a second basic operating mode according to the first embodiment of the present invention;

FIG. 5 is a schematic diagram showing a flow of the heat medium in an overheat driving mode according to the first embodiment of the present invention;

FIG. 6 is a schematic diagram showing the flow of the heat medium in the overheat driving mode according to the first embodiment of the present invention;

FIG. 7 is a schematic diagram showing a flow of the heat medium in a little heat driving mode according to the first embodiment of the present invention;

FIG. 8 is another schematic diagram showing the flow of the heat medium in the little heat driving mode according to the first embodiment of the present invention.

FIG. 9 is a schematic diagram showing a flow of the heat medium in a direct cooling mode according to the first embodiment of the present invention;

FIG. 10A is a perspective view showing a heat collector, a heat-generating instrument, and a heat-generating element according to a second embodiment of the present invention;

FIG. 10B is a cross-sectional view showing the state of fitting the heat collector to the heat-generating instrument according to a second embodiment of the present invention;

FIG. 11A is a perspective view showing a heat collector in a state of fitting the heat collector to a heat-generating instrument, to which a heat-generating element is fitted according to a third embodiment of the present invention;

FIG. 11B is a cross-sectional view showing the state of fitting the heat collector to the heat-generating instrument according to a third embodiment of the present invention in;

FIG. 12A is a perspective view showing a state of fitting the heat collector to a heat-generating instrument, to which a heat-generating element is fitted according to a fourth embodiment of the present invention;

FIG. 12B is a cross-sectional view showing the state of fitting the heat collector to the heat-generating instrument according to a fourth embodiment of the present invention;

FIG. 13A is a perspective view showing a state of fitting the heat collector to a heat-generating instrument, to which a heat-generating element is fitted according to a fifth embodiment of the present invention;

FIG. 13B is a cross-sectional view showing the state of fitting the heat collector to the heat-generating instrument according to a fifth embodiment of the present invention;

FIG. 14A is a perspective view showing a state of fitting the heat collector to a heat-generating instrument, to which a heat-generating element is fitted according to a sixth embodiment of the present invention;

FIG. 14B is a cross-sectional view showing the state of fitting the heat collector to the heat-generating instrument according to a sixth embodiment of the present invention;

FIG. 15A is a perspective view showing a state of fitting the heat collector to a heat-generating instrument, to which a heat-generating element is fitted according to a seventh embodiment of the present invention;

FIG. 15B is a cross-sectional view showing the state of fitting the heat collector to the heat-generating instrument according to a seventh embodiment of the present invention;

FIG. 16A is another perspective view showing the state of fitting the heat collector to the heat-generating instrument, to which the heat-generating element is fitted according to the seventh embodiment of the present invention;

FIG. 16B is another cross-sectional view showing the state of fitting the heat collector to the heat-generating instrument according to the seventh embodiment of the present invention;

FIG. 17 is a schematic diagram of a heat collector according to an eighth embodiment of the present invention;

FIG. 18 is a perspective view of the heat collector according to the eighth embodiment of the present invention;

FIG. 19 is a partially enlarged view of the heat collector according to the eighth embodiment of the present invention;

FIG. 20 is a schematic diagram of a heat collector according to a ninth embodiment of the present invention;

FIG. 21A is a schematic diagram of a heat collector according to a tenth embodiment of the present invention;

FIG. 21B is a schematic diagram of a heat collector according to a tenth embodiment of the present invention;

FIG. 22 is a schematic diagram of a heat collector according to an eleventh embodiment of the present invention;

FIG. 23 is a schematic diagram of another heat collector according to the eleventh embodiment of the present invention;

FIG. 24 is a schematic diagram of another heat collector according to the eleventh embodiment of the present invention;

FIG. 25 is a schematic diagram of another heat collector according to the eleventh embodiment of the present invention;

FIG. 26 is a schematic diagram of another heat collector according to the eleventh embodiment of the present invention;

FIG. 27 is a schematic diagram of another heat collector according to the eleventh embodiment of the present invention;

FIG. 28 is a perspective view of the heat collector according to the eleventh embodiment of the present invention; and

FIG. 29 is a perspective view of a heat collector according to a twelfth embodiment of the present invention.

### DETAILED DESCRIPTION OF THE PREFERRED EMBODIMENTS

(First Embodiment)

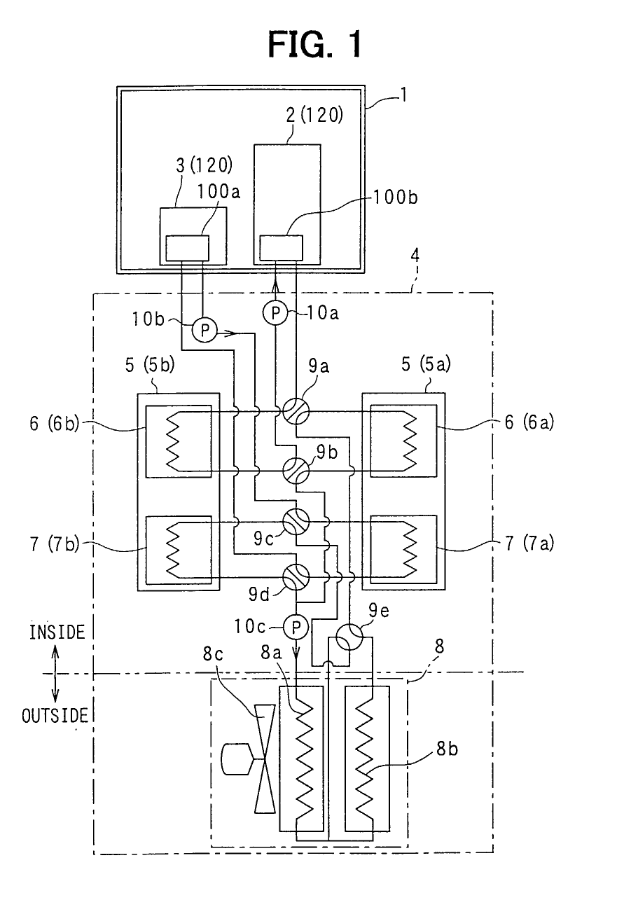

The present embodiment adopts a heat collector to a cooling system for cooling an electronic instrument in a cellular phone base station 1. FIG. 1 is a schematic diagram of the cooling system.

Moreover, provided in the cellular phone base station 1, are a first heat-generating element 2 including a circuit control panel, a battery and the like, a second heat-generating element 3 including a radiowave output amplifier, a radiowave output control panel, a rectifier and the like, and a refrigerator 4 (an area surrounded by dash and dotted lines) for cooling the heat-generating elements 2 and 3.

Here, the refrigerator 4 is an absorption type refrigerator, which works by absorbing heat from the first heat-generating element 2 and heating an absorbent with the absorbed heat. In the following, description will be made regarding the refrigerator 4.

Here, the absorbent absorbs a refrigerant (which is water in this embodiment) and desorbs the absorbed refrigerant by means of heating. In this embodiment, a solid absorbent such as silica gel or zeolite is adopted.

An absorber 5 is maintained to constitute almost a vacuum inner space and the refrigerant is filled therein. A first heat exchanger 6 for exchanging heat between the absorbent and a heat medium, and a second heat exchanger 7 for exchanging heat between the heat medium and the refrigerant filled inside the absorber 5 are housed in the absorber 5. Here, in this embodiment, water mixed with an ethylene glycol type antifreeze liquid is adopted as the heat medium.

Note that this embodiment includes a plurality of absorbers 5a and 5b, and the absorber 5a on the right side of the sheet (hereinafter referred to as a first absorber 5a) and the absorber 5b on the left side of the sheet (hereinafter referred to as a second absorber 5b) have the same design and construction. Accordingly, both absorbers are collectively denoted as the absorber 5 when reference is made collectively thereto. Furthermore, the suffix “a” added to the heat exchanger 6 or 7 indicates that the relevant exchanger is a heat exchanger inside the first absorber 5a, and the suffix “b” added to the heat exchanger 6 or 7 indicates that the relevant exchanger is a heat exchanger inside the second absorber 5b. The absorber 5a on the right side of the sheet will be hereinafter referred to as the first absorber 5a and the absorber 5b on the left side of the sheet will be hereinafter referred to as the second absorber 5b.

An outdoor heat exchanger 8 is placed outside a structure of the cellular phone base station 1 for exchanging heat between the heat medium and outdoor air (a subject for heat radiation). The outdoor heat exchanger 8 includes first and second radiators 8a and 8b, and a fan 8c to blow cooling wind. The first radiator 8a is provided on a more upstream side of a flow of the cooling wind than the second radiator 8b.

Moreover, a first heat collector 100a is provided for collecting heat generated by the first heat-generating element 2 and for exchanging the collected heat with the heat medium. A second heat collector 100b is provided for collecting heat generated by the second heat-generating element 3 and for exchanging the collected heat with the heat medium. Valves 9a to 9e are rotary valves for switching flows of the heat medium, and reference numerals 10a to 10c denote pumps for circulating the heat medium. Note that the first heat collector 100a and the second heat collector 100b have the same structure. Therefore, the heat collectors 100a and 100b will be hereinafter collectively referred to as the heat collector 100, and the first heat-generating element 2 and the second heat-generating element 3 will be hereinafter collectively referred to as the heat-generating element 120.

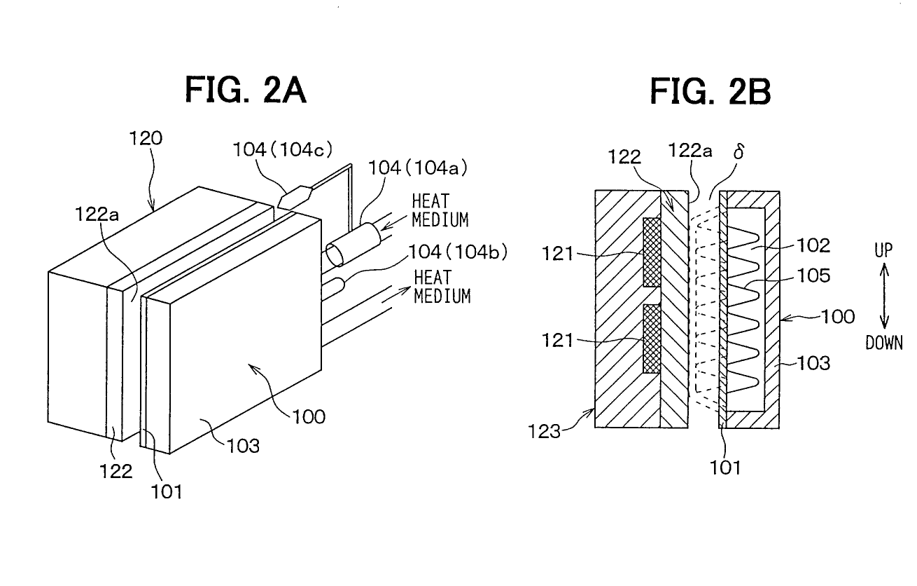

Next, description will be made regarding the heat collector 100 based on FIGS. 2A and 2B. FIG. 2A is a perspective view showing a state of fitting the heat collector 100 to the heat-generating instrument 120, to which the heat-generating element 121 is fitted. FIG. 2B is a cross-sectional view showing the state of fitting the heat collector 100 to the heat-generating instrument 120.

A heat-radiating plate 122 constitutes the radiating surface 122a of the heat-generating instrument 120 by contacting with the heat-generating element 121. A cover 123 is fixed to the heat-radiating plate 122 for covering the heat-generating element 121. The cover 123, the heat-radiating plate 122, the heat-generating element 121 and the like collectively constitute the heat-generating instrument 120.

Meanwhile, the heat collector 100 includes a thin-film heat-collecting diaphragm 101 for being deformed upon receipt of pressure of the fluid heat medium so as to contact with the radiating surface 122a, a heat collector casing 103 fixing the heat-collecting diaphragm 101 thereon for constituting a pressure chamber 102 to apply fluid pressure to the heat-collecting diaphragm 101, valve devices 104 provided on a heat medium inlet side of the pressure chamber 102 to open and close passages for the heat medium, waved fin 105 joined to a plane on the pressure chamber 102 side of the heat-collecting diaphragm 101 for promoting heat exchange between the heat medium and collected heat, and the like.

Incidentally, each valve device 104 includes an electromagnetic valve 104a for opening and closing the passage for the heat medium, a pressure sensor (pressure detecting means) 104b for detecting pressure inside the pressure chamber 102, a temperature sensor (temperature detecting means) 104c for detecting a temperature of the heat-radiating plate 122 or the heat-collecting diaphragm 101 (the temperature of the heat-radiating plate 122 is selected in this embodiment). An electronic control unit (not shown) exists for opening and closing the electromagnetic valve 104a in accordance with signals detected by the pressure sensor 104b and the temperature sensor 104c, electric signals of the heat-generating element 121, and the like.

As will be described later, the heat-radiating plate 122 and heat-collecting diaphragm 101 are separated from each other with the provision of a given gap 6 as illustrated with a solid line in FIG. 2B when the fluid pressure is not applied to the pressure chamber 102. Moreover, the heat-radiating plate 122 is preferably made of highly heat conductive metal such as copper, lead, aluminum, iron, gold, silver, beryllium, magnesium, tungsten or zinc.

Next, description will be made regarding operations and characteristics of the heat collector 100. The pumps 10a and 10b are activated to fill and circulate the heat medium in the pressure chamber 102. In this way, the fluid pressure owing to the heat medium acting on the pressure chamber 102 side of the heat-collecting diaphragm 101 grows larger than the pressure on the heat-radiating plate 122 side of the heat-collecting diaphragm 101 (the atmospheric pressure). Accordingly, the heat-collecting diaphragm 101 is deformed in an expanding manner until contacting with the heat-radiating plate 122 as illustrated with wavy (dashed) lines in FIG. 2B.

Therefore, the heat-collecting diaphragm 101 contacts with the heat-radiating plate 122 in the state that the fluid pressure is applied thereto. As a result, the entire heat-collecting diaphragm 101 contacts with the heat-radiating plate 122 almost uniformly and contact thermal resistance between the heat-collecting diaphragm 101 and the heat-radiating plate 122 is reduced. Therefore a radiation quantity from the heat-radiating plate 122 to the heat collector 100 is increased.

Moreover, upon repairing or replacing the heat-generating instrument 120, the pumps 10a and 10b are stopped and the electromagnetic valve 104a is closed. In this way, supply of the heat medium to the pressure chamber 102 is stopped. Accordingly, the fluid pressure to be applied to the heat-collecting diaphragm 101 disappears and the heat-collecting diaphragm 101 is thereby separated from the heat-radiating plate 122.

Therefore, it is possible to detach the heat collector 100 from the heat-generating instrument 120 without draining the heat medium out of the heat collector 100. Accordingly, it is possible to enhance workability of repairing or replacing the heat-generating instrument 120.

Moreover, when the pressure detected by the pressure sensor 104b falls from a predetermined pressure value, the electronic control unit regards such a fall as an occurrence of leakage of the heat medium in a certain region of the heat collector 100, that is, in the cooling system. Accordingly, the electronic control unit closes the electromagnetic valve 104a and stops the pumps 10a and 10b. If only the pump 10c is in operation, then the electronic control unit stops the pump 10c.

In this way, it is possible to minimize the leakage of the heat medium and to start an operation for repairing or replacing the heat-generating instrument 120 immediately without carrying out a switching operation for closing the electromagnetic valve 104a nor a switching operation for stopping the pumps 10a and 10b or the pump 10c in the event of repairing or replacing the heat-generating instrument 120. Accordingly, it is possible to enhance workability of repairing or replacing the heat-generating instrument 120.

Similarly, when the temperature detected by the temperature sensor 104c falls from a predetermined temperature or when there is no electric signal from the heat-generating element 121, the electronic control unit regards such an aspect as an occurrence of trouble at the heat-generating instrument 120. Accordingly, the electronic control unit closes the electromagnetic valve 104a and stops the pumps 10a and 10b. If only the pump 10c is in operation, then the electronic control unit stops the pump 10c.

In this way, it is possible to minimize the leakage of the heat medium and to start an operation for repairing or replacing the heat-generating instrument 120 immediately without carrying out a switching operation for closing the electromagnetic valve 104a nor a switching operation for stopping the pumps 10a and 10b or the pump 10c in the event of repairing or replacing the heat-generating instrument 120. Accordingly, it is possible to enhance workability of repairing or replacing the heat-generating instrument 120.

Whereas the pumps 10a and 10b or the pump 10c are stopped simultaneously with closing of the electromagnetic valve 104a in this embodiment, the electromagnetic valve 104a may be closed while retaining the pumps 10a and 10b or the pump 10c in operation, or alternatively, the pumps 10a and 10b or the pump 10c may be stopped while retaining the electromagnetic valve 104a in an open position. However, the pumps 10a and 10b or the pump 10c needs to be stopped in the event of detaching the heat-generating instrument 120 from the heat collector 100.

Next, description will be made regarding operations of the cooling system according to an embodiment of the present invention.

1. Basic Operating Mode of the Refrigerator 4 (The Absorption Refrigerator)

This mode refers to a driving mode of switching first and second basic operating modes as will be described below in every predetermined time period. Additionally, the time period is appropriately selected based on time necessary for desorbing the refrigerant which is absorbed in the absorbent.

In this embodiment, it should be noted that the first heat-generating element 2 is cooled (heat-absorbed) down to 150° C. or below, and the second heat-generating element 3 is cooled down to about the temperature of the outside air (35° C. to 45° C.) or below. Relevant specifications are determined such that the refrigerator 4 exerts predetermined refrigeration capability in a temperature range from 70° C. to 100° C. inclusive.

1.1 First Basic Operating Mode

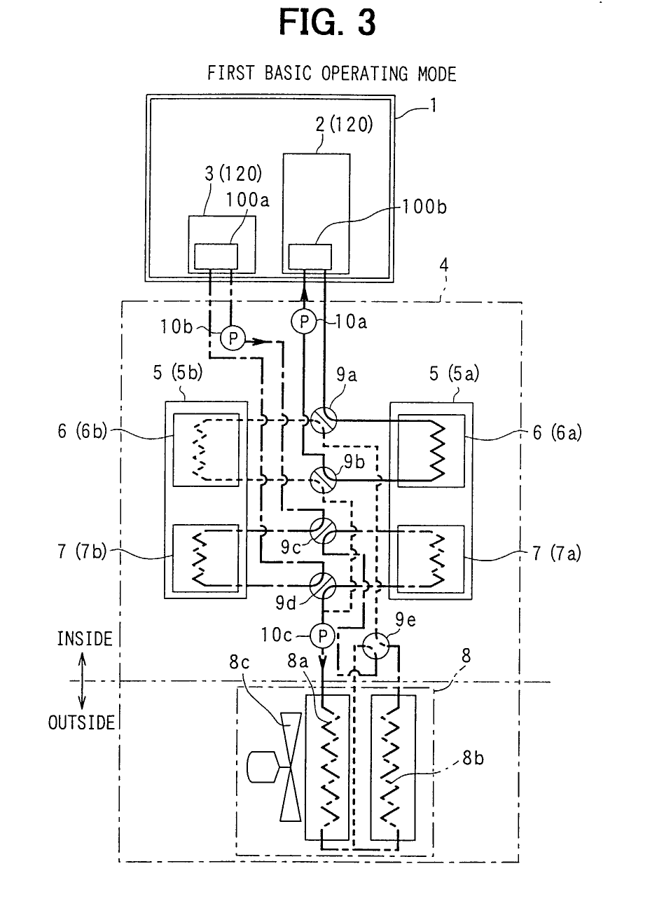

In this mode, as shown in FIG. 3, the heat medium is circulated between the second heat collector 100b and the second heat exchanger 7b of the second absorber 5b, whereby the refrigerant inside the second absorber 5b is evaporated and the cooled heat medium is supplied to the second heat collector 100b. In this way, the second heat-generating element 3 is cooled and the gaseous refrigerant evaporated inside the second absorber 5b, that is, water vapor, is absorbed by the absorbent inside the second absorber 5b.

In this event, the absorbent generates heat in an amount relevant to heat of condensation. In addition, since absorption capacity is reduced if the temperature of the absorbent rises, the heat medium cooled by the outdoor heat exchanger 8 is supplied to the first heat exchanger 6b of the second absorber 5b to cool down the absorbent.

Meanwhile, regarding the first heat exchanger 6a of the first absorber 5a, the heat absorbed into the heat medium with the first heat collector 100a is supplied to the absorbent in the first absorber 5a via the heat medium to heat the absorbent. The refrigerant absorbed into the absorbent is thereby desorbed, and the heat medium cooled by the outdoor heat exchanger 8 is supplied to the second heat exchanger 7a of the first absorber 5a. Moreover, the desorbed gaseous refrigerant (the water vapor) is cooled down and condensed in the second heat exchanger 7a.

The absorber 5 in the state of exerting refrigeration capability by evaporating the refrigerant and thereby absorbing the evaporated gaseous refrigerant with the absorbent will be hereinafter referred to as the “absorber 5 in process of absorption.” Meanwhile, the absorber 5 in the state of desorbing the absorbed refrigerant by heating the absorbent and thereby cooling and condensing the desorbed refrigerant will be referred to as the “absorber 5 in process of desorption.”

1.2 Second Basic Operating Mode

This mode is a reverse of the first basic operating mode, in which the first absorber 5a is set to an absorption process and the second absorber 5b is set to a desorption process.

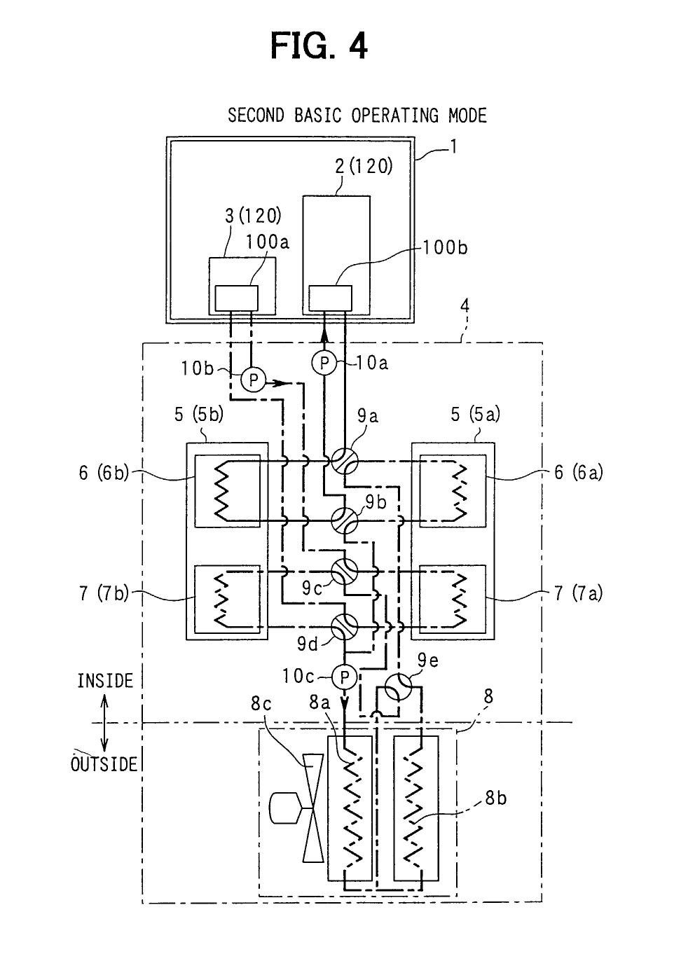

As shown in FIG. 4, the heat medium is circulated between the second heat collector 100b and the second heat exchanger 7a of the first absorber 5a, whereby the refrigerant inside the first absorber 5a is evaporated and the cooled heat medium is supplied to the second heat collector 100b. In this way, the second heat-generating element 3 is cooled down and the gaseous refrigerant (the water vapor) evaporated inside the first absorber 5a is absorbed by the absorbent inside the first absorber 5a.

In this event, the heat medium cooled by the outdoor heat exchanger 8 is supplied to the first heat exchanger 6a of the first absorber 5a to cool down the absorbent.

Meanwhile, regarding the first heat exchanger 6b of the second absorber 5b, the heat absorbed in the heat medium at the first heat collector 100a is supplied to the absorbent of the second absorber 5b via the heat medium to heat the absorbent. Accordingly, the refrigerant absorbed into the absorbent is thereby desorbed, and the heat medium cooled by the outdoor heat exchanger 8 is supplied to the second heat exchanger 7b of the second absorber 5b. Moreover, the desorbed gaseous refrigerant is cooled and condensed in the second heat exchanger 7b.

2. Overheat Driving Mode

This driving mode is a mode to be executed when a heat value of the first heat-generating element 2 exceeds a predetermined value absorbable by the refrigerator 4. Here, the predetermined heat value refers to a value obtained by subtracting maximum refrigeration capacity of the refrigerator 4 by a maximum performance coefficient of the refrigerator 4, for example.

To be concrete, upon switching between the first basic operating mode and the second basic operating mode, the valve 9b for switching a heat medium outlet side of the first heat exchanger 6 is switched and thereby activated prior to the valve 9a for switching a heat medium inlet side of the first heat exchanger 6, and then the valve 9a is activated after passage of a predetermined time period.

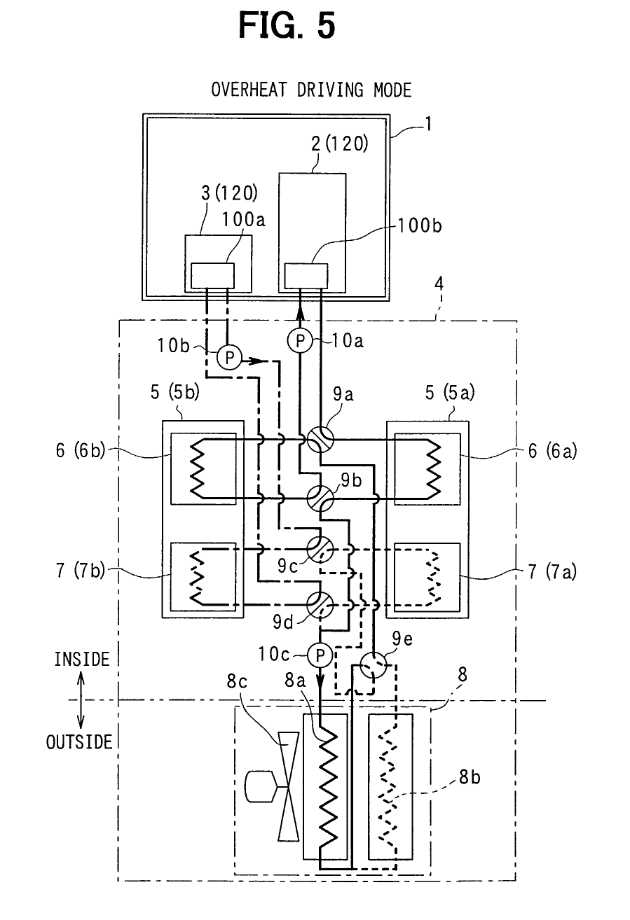

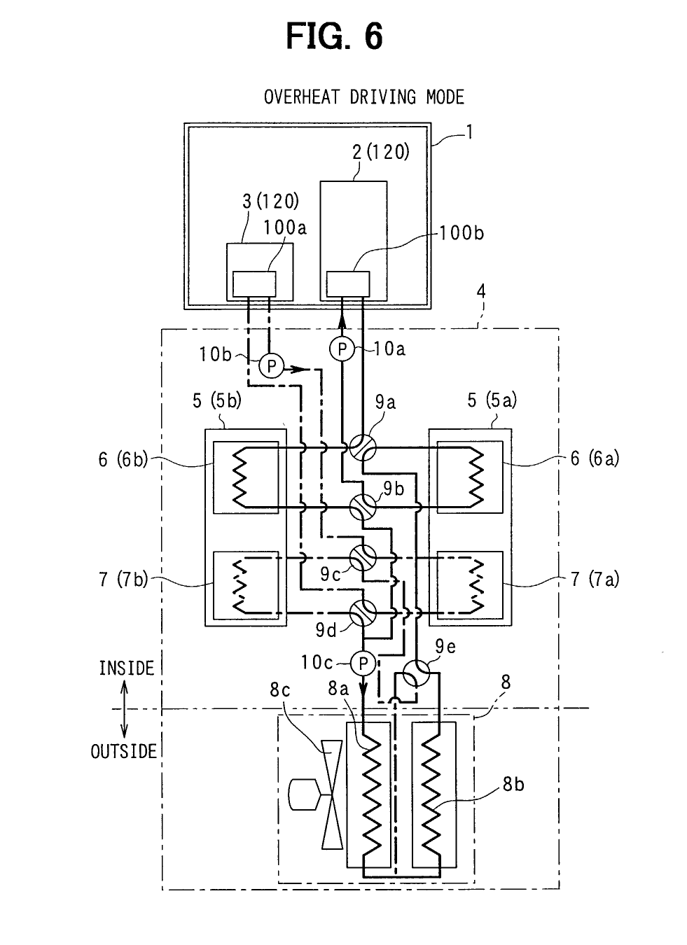

In this way, as shown in FIGS. 5 and 6, the heat absorbed in the heat medium at the first heat collector 100a is not supplied to the absorbent, that is, to the refrigerator 4. Instead, the heat is dissipated to the outside air from the outdoor heat exchanger 8.

Note that time for executing the overheat driving mode is to be appropriately determined based on the heat amount of the first heat-generating element 2, the absorbable heat value of the refrigerator 4, the temperature of the outside air and the like.

FIG. 5 illustrates the overheat driving mode to be executed upon shifting from the first basic operating mode to the second basic operating mode. Meanwhile, FIG. 6 illustrates the overheat driving mode to be executed upon shifting from the second basic operating mode to the first basic operating mode.

3. Little Heat Driving Mode

This mode is to be executed when the heat value of the first heat-generating element 2 falls from a predetermined value required for operating the refrigerator 4.

Upon switching between the first basic operating mode and the second basic operating mode, the valve 9a for switching the heat medium inlet side of the first heat exchanger 6 is switched and thereby activated prior to the valve 9b for switching the heat medium outlet side of the first heat exchanger 6, and then the valve 9b is activated after passage of a predetermined time period.

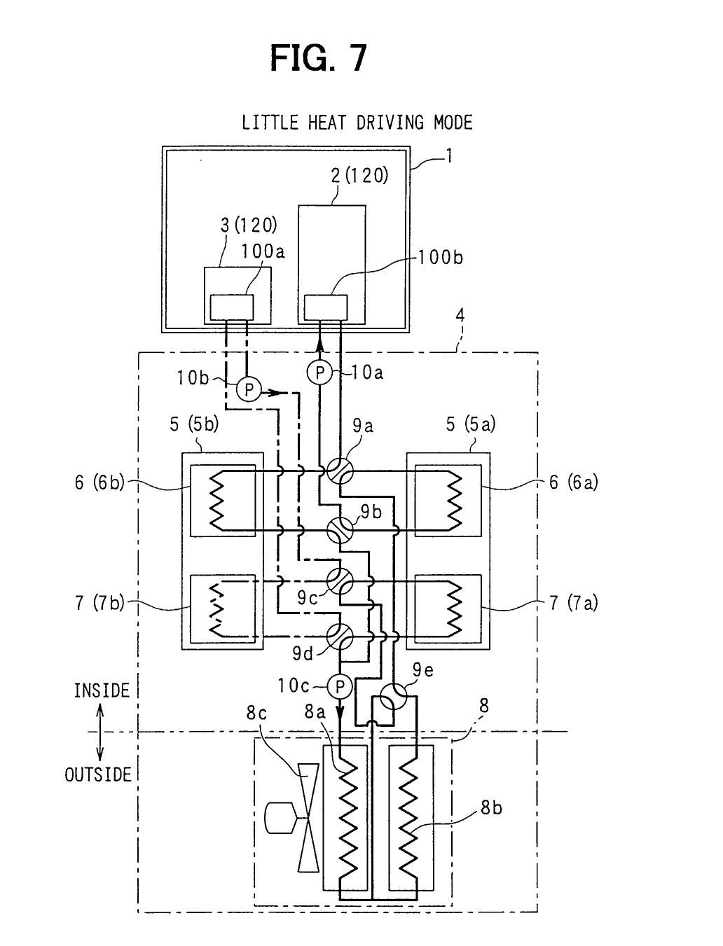

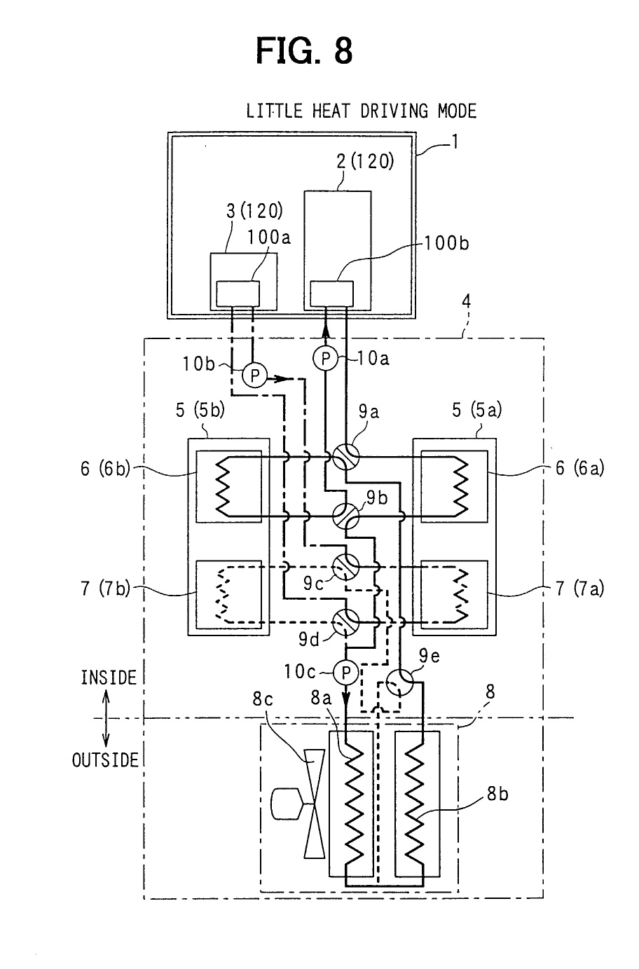

In this way, as shown in FIGS. 7 and 8, the heat medium supplied to the first heat exchanger 6 for heating the absorbent returns to the first heat collector 100a without flowing into the outdoor heat exchanger 8. Therefore, it is possible to supply the heat generated by the first heat-generating element 2 to the refrigerator 4 without waste.

Note that time for executing the little heat driving mode is also to be appropriately determined based on the heat amount of the first heat-generating element 2, the absorbable heat value of the refrigerator 4, that is, the absorbent, the temperature of the outside air and the like, as similar to the time for the overheat driving mode. FIG. 7 illustrates the little heat driving mode to be executed upon shifting from the first basic operating mode to the second basic operating mode. Meanwhile, FIG. 8 illustrates the little heat driving mode to be executed upon shifting from the second basic operating mode to the first basic operating mode.

4. Direct Cooling Mode

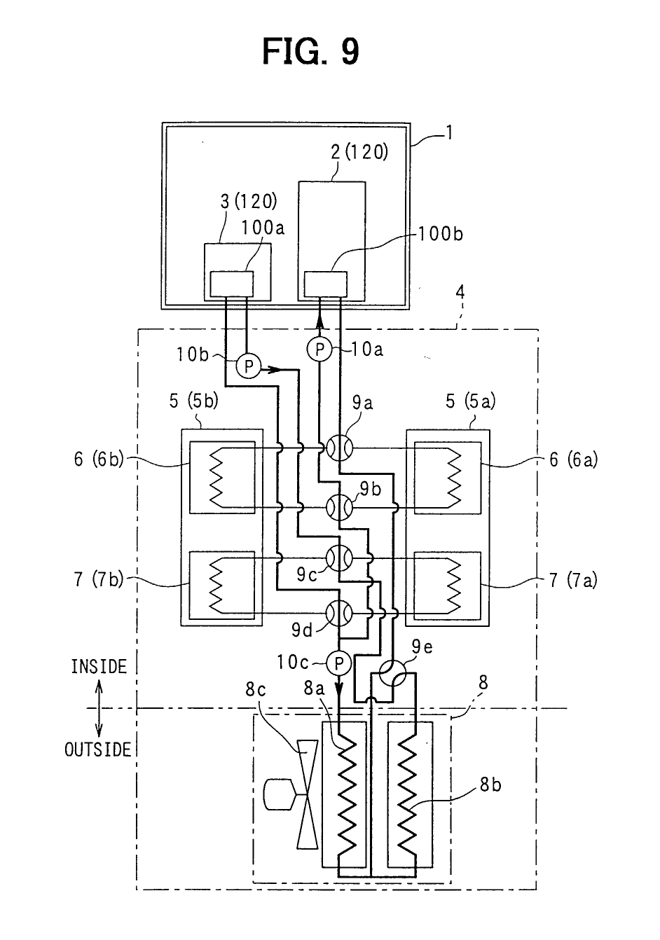

This mode is to be executed when the temperature of the outside air becomes sufficiently low such as in winter and the temperature of the outside air thereby becomes lower than a cooling temperature of the second heat-generating element 3, that is, lower than an allowable heat-resistant temperature of the second heat-generating element 3, or when the refrigerator 4 is out of order. As shown in FIG. 9, the pumps 10a and 10b are stopped and the heat medium cooled only when the first radiator 8a is supplied to the first heat-generating element 2, that is, to the first heat collector 100a. Meanwhile, the heat medium cooled with the first radiator 8a and the second radiator 8b is supplied to the second heat-generating element 3, that is, to the second heat collector 110b.

Note that the temperature of the outside air is detected with an unillustrated outside air temperature sensor. In this embodiment, this mode is executed when the detected value is 15° C. or below.

Moreover, regarding judgment as to whether the refrigerator 4 is in or out of order, the refrigerator 4 is deemed to be disabled in any of the following events when the pressure inside the absorber 5 rises to a predetermined value (which is 70 KPa in this embodiment) or higher, when the temperature of the heat medium flowing out of the second heat exchanger 7 of the absorber 5 in process of absorption rises to a predetermined temperature (which is 20° C. in this embodiment) or higher, when the temperature of the heat medium flowing out of the second heat exchanger 7 of the absorber 5 in process of absorption becomes equal to the temperature of the heat medium at an entrance of the second heat exchanger 7, and when the temperature of the heat medium flowing into the first heat exchanger 6 of the absorber 5 and the temperature of the heat medium flowing out of the first heat exchanger 6 become equal.

(Second Embodiment)

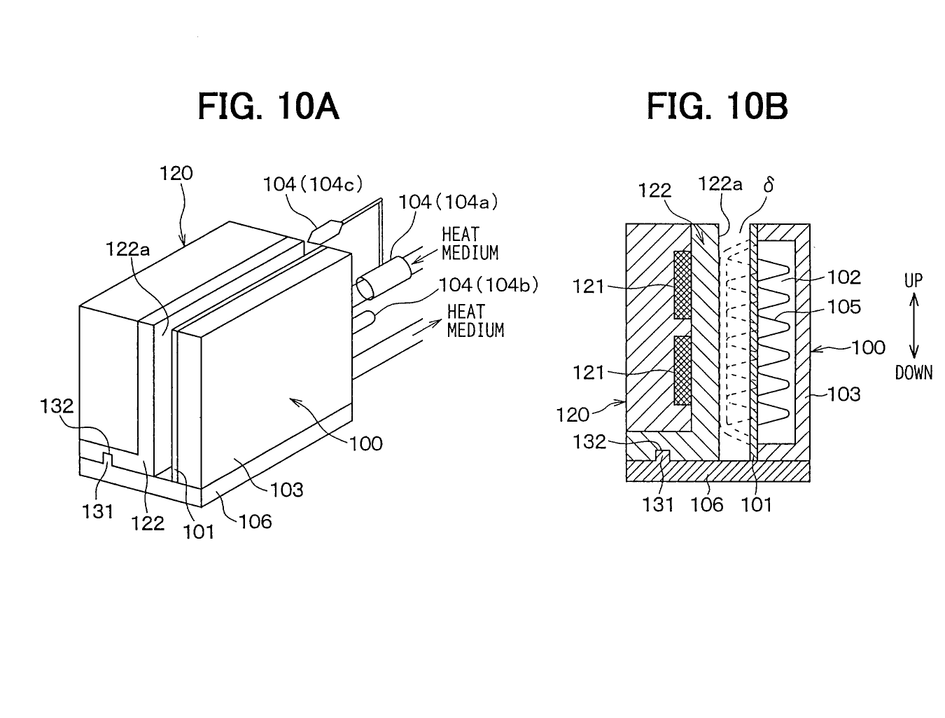

In this embodiment, as shown in FIGS. 10A and 10B, a positioning protrusion 131 and a positioning groove 132 for engaging with the positioning protrusion 131 are provided as positioning means for setting positions of a heat-generating instrument 120 and a heat collector 100. A heat collector casing 103 is fixed to a plate base member 106 by a bonding method such as welding, bolts, or the like, and the positioning protrusion 131 is provided on the base member 106. The positioning groove 132 is provided on the heat-generating instrument 120 (which is a heat-radiating plate 122 in this embodiment).

In this way, upon refitting the heat-generating instrument 120 to the heat collector 100 after the heat-generating instrument 120 is detached from the heat collector 100, for example, it is possible to control a dimension of a gap δ between the heat-radiating plate 122 and the heat collector 100 easily and accurately. Therefore, it is possible to facilitate an operation of repairing or replacing the heat-generating instrument 120.

Moreover, since accurate control of the dimension of the gap δ is effectuated, it is possible to accurately control a degree of close contact (pressure on a contact surface) between a heat-collecting diaphragm 101 and the heat-radiating plate 122. Therefore, substantial reduction in an amount of radiation from the heat-radiating plate 122 to the heat collector 100 can be avoided upon an operation of repairing or replacing the heat-generating instrument 120.

(Third Embodiment)

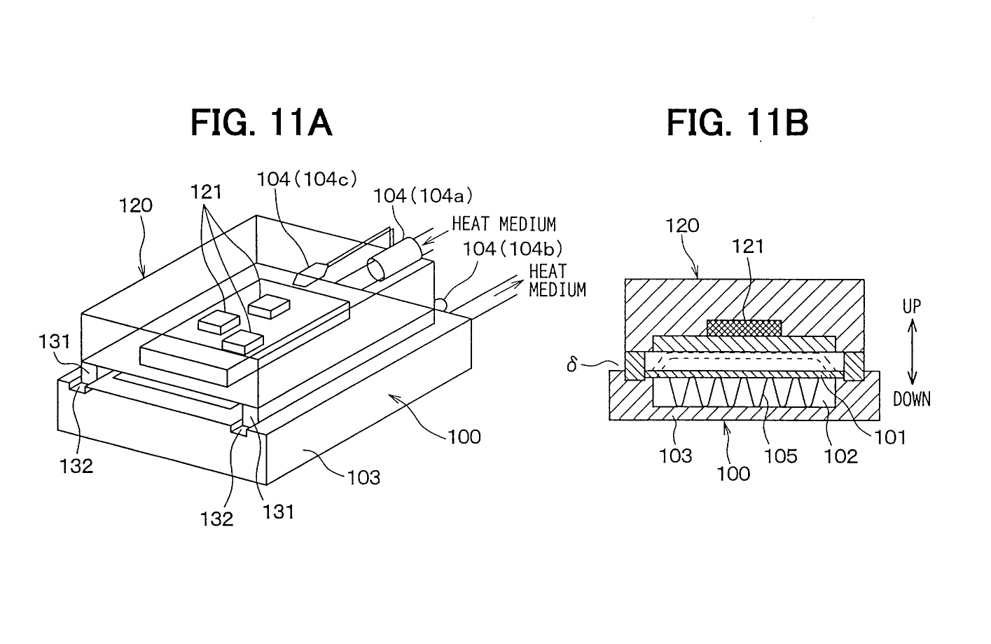

This embodiment is a modified example of the second embodiment. As shown in FIG. 11A, a plurality of positioning protrusions 131 and a plurality of positioning grooves 132 (which each number two in this embodiment) are provided. A heat collector 100 and a heat-generating instrument 120 are horizontally disposed so that a heat-radiating plate 122 and a heat-collecting diaphragm 101 are placed substantially horizontally.

(Fourth Embodiment)

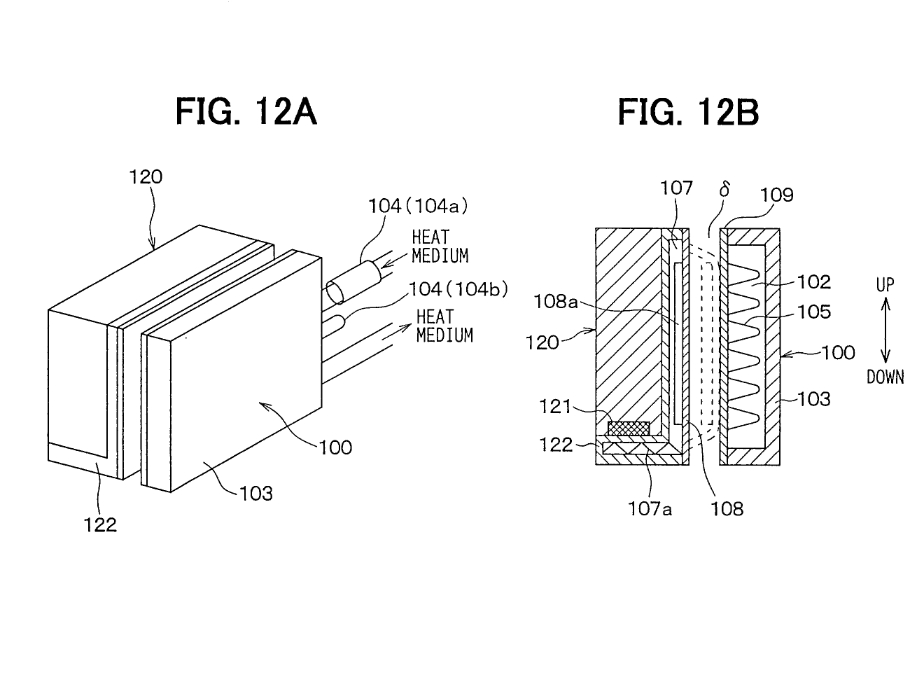

In the above-described embodiment, the heat-collecting diaphragm 101 is expanded in a deformed manner with the fluid pressure of the heat medium pumped from (provided by) the pumps 10a and 10b or the pump 10c. However, as shown in FIG. 12, this embodiment constitutes an enclosed pressure chamber 107, of which inner pressure varies upon receipt of heat from a heat-generating instrument 120, with a heat-radiating plate 122 and a thin-film heat-radiating diaphragm 108 being deformed in accordance with the pressure inside the pressure chamber 107. In addition, instead of the heat-collecting diaphragm 101, a rigid heat collecting plate 109, which is hardly deformed by the fluid pressure of the heat medium pumped from the pumps 10a and 10b or the pump 10c, is fixed to a heat collector casing 103.

Moreover, the pressure chamber 107 is filled with a refrigerant. The refrigerant has a boiling point and latent heat of vaporization to the extent that the heat generated from a heat-generating element 121 can evaporate the refrigerant. In addition, a fin 108a for promoting heat exchange between the refrigerant and the heat-radiating diaphragm 108 (a heat-collecting plate 109) is joined to the pressure chamber 107 side of the heat-radiating diaphragm 108.

The refrigerant to be filled in the pressure chamber 107 is preferably selected, for example, from water, alcohol, chlorofluorocarbon, ammonia, lithium bromide, oil, water mixed with an antifreeze liquid of an ethylene glycol series, or the like. Numerous options exist for a refrigerant and the user is not limited to any of the above.

The fin 108a is formed into a thin strip shape, and longitudinal sides of the film 108a extend in a vertical direction so that the condensed refrigerant can flow or dribble smoothly into a liquid refrigerant reservoir 107a disposed on a bottom side. The heat-collecting plate 109 is preferably made of a highly heat conductive metal such as copper, lead, aluminum, iron, gold, silver, beryllium, magnesium, tungsten, or zinc.

Next, description will be made regarding characteristic operations and effects of this embodiment. When the heat-generating element 121, that is, the heat-generating instrument 120 generates heat, the refrigerant present inside the pressure chamber 107 in the vicinity of the heat-generating element 121 is evaporated, whereby the pressure inside the pressure chamber 107 is increased. Accordingly, the heat-radiating diaphragm 108 is deformed so as to expand toward the heat-collecting plate 109, whereby the heat-radiating diaphragm 108 and the heat-collecting plate 109 contact with each other as illustrated with dashed lines in FIG. 12B.

Therefore, the heat-radiating diaphragm 108 contacts the heat-collecting plate 109 when the fluid pressure, that is, vapor pressure, inside the pressure chamber 107 is applied thereto. As a result, the entire heat-radiating diaphragm 108 contacts the heat-collecting plate 109 substantially uniformly and contact thermal resistance between the heat-radiating diaphragm 108 and the heat-collecting plate 109 is reduced, whereby a radiation quantity from the heat-radiating diaphragm 108 to the heat-collecting plate 109 is increased.

Meanwhile, the refrigerant evaporated at the liquid refrigerant reservoir 107a by absorbing the heat from the heat-generating element 121 is cooled and condensed by the fin 108a, and thereby flows downward on a surface of the fin 108a. Thereafter, the refrigerant is heated again and thereby evaporated by the heat-generating element 121 at the liquid refrigerant reservoir 107a.

In this way, according to this embodiment, the heat-radiating diaphragm 108 is deformed by use of the heat generated by the heat-generating instrument 120. Therefore, it is possible to reduce pumping work of the pumps 10a and 10b or the pump 10c for pumping the heat medium by pressure, or to reduce ejection pressure of the pump. Therefore, it is possible to adopt pumps with a relatively small ejection pressure for the pumps 10a and 10b or the pump 10c. Accordingly, it is possible to reduce manufacturing costs of the heat collector 100, that is, the cooling system.

Moreover, upon an operation of repairing or replacing the heat-generating instrument 120, the heat-radiating diaphragm 108 is spontaneously separated from the heat-collecting plate 109 just by turning off the heat-generating element 121. Accordingly, it is possible to form parts of the heat collector 100 in a region of circulating the heat medium such as the heat-collecting plate 109, the heat collector casing 103 and the like, separately from parts on the pressure chamber 107 side thereof such as the heat-radiating diaphragm 108.

Therefore, it is possible to detach the heat collector 100 from the heat-generating instrument 120 without draining the heat medium out of the heat collector 100. Accordingly, it is possible to enhance workability of repairing or replacing the heat-generating instrument 120.

Since operations of valve devices 104 are similar to the previous embodiments, detailed description thereof is omitted.

(Fifth Embodiment)

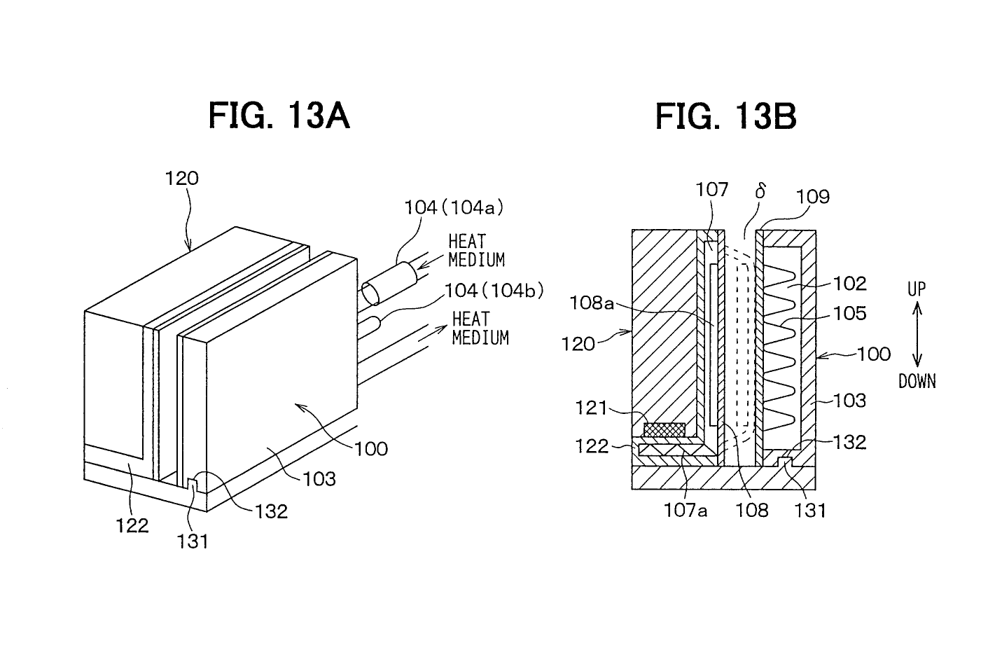

This embodiment is equivalent to providing the fourth embodiment with a positioning protrusion 131 and a positioning groove 132 for engaging with the positioning protrusion 131 as positioning means for setting positions of a heat-generating instrument 120 and a heat collector 100, as similar to the second embodiment. However, in this embodiment, a pressure chamber 107 side of the heat collector 100 such as a heat-radiating diaphragm 108, the heat-generating instrument 120 and a base member 106 are integrated by a bonding method such as welding or bolts, and the positioning groove 132 is provided on a heat collector casing 103 as shown in FIG. 13.

(Sixth Embodiment)

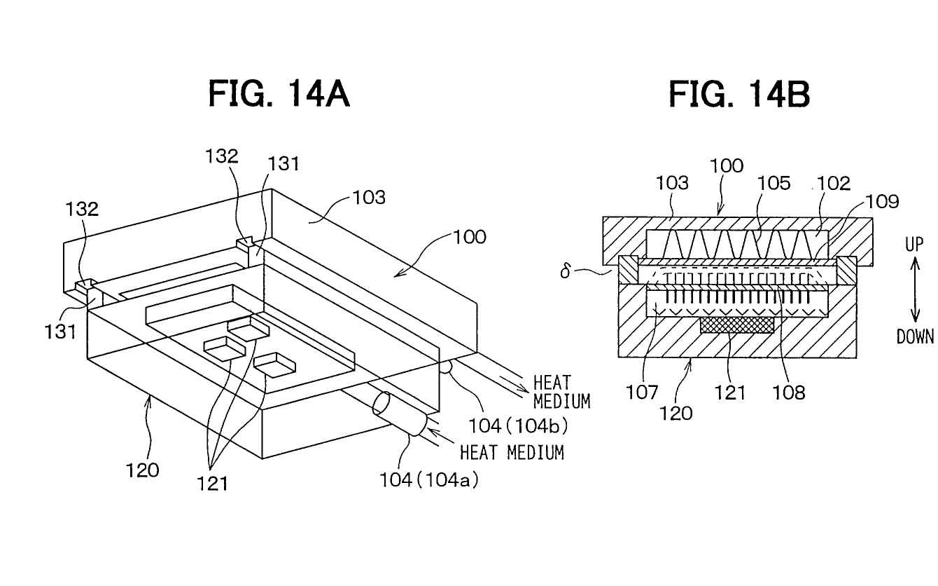

This embodiment is equivalent to adopting the third embodiment to the fourth embodiment. As shown in FIGS. 14A and 14B, pluralities of positioning protrusions 131 and positioning grooves 132 (which is two in this embodiment) are provided and a heat collector 100 and a heat-generating instrument 120 are horizontally disposed so that a heat-radiating plate 109 and a heat-radiating diaphragm 108 are placed substantially horizontally.

Note that the heat-generating instrument 120 is disposed below the heat collector 100 in this embodiment, because a liquid refrigerant reservoir 107a needs to be located at a lower side.

(Seventh embodiment)

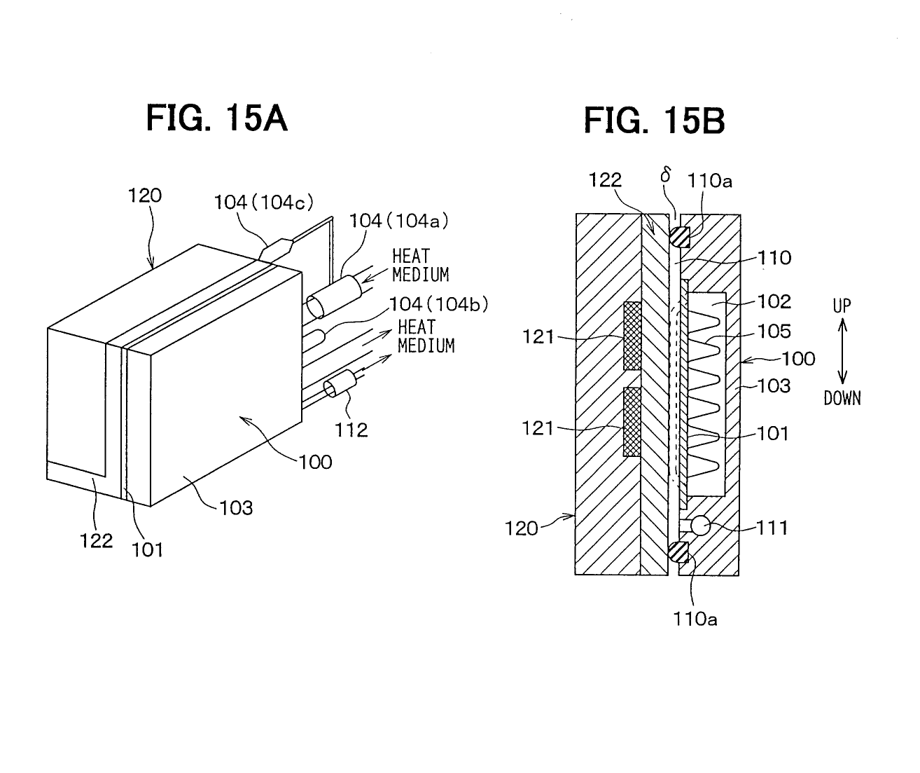

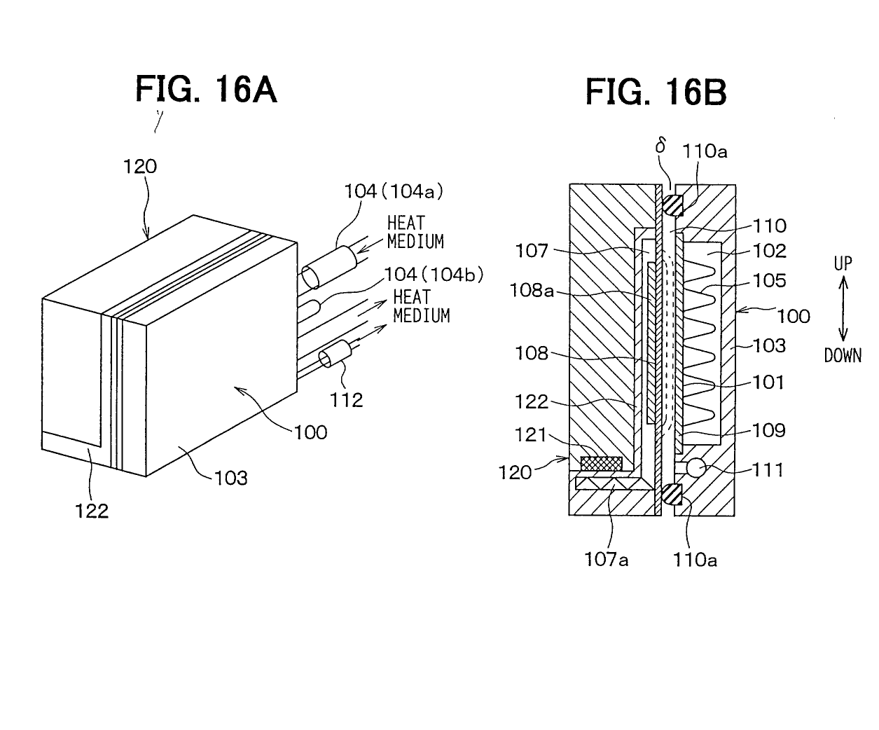

In this embodiment, as shown in FIGS. 15A, 15B, 16A, and 16B, packing such as an O-ring 110a is disposed so as to surround heat-collecting diaphragm 101 and heat-radiating diaphragm 108, that is, pressure chambers 102 and 107. Accordingly, an enclosed space 110 is provided outside the heat-collecting diaphragm 101 and heat-radiating diaphragm 108, that is, the pressure chambers 102 and 107. In this way, a heat-radiating plate 122 or a heat-collecting plate 109, which is a heat-transferring surface, and the heat-collecting diaphragm 101 and heat-radiating diaphragm 108 are closely contacted to each other without gaps by reducing pressure inside the enclosed space 110.

Note that FIGS. 15A and 15B illustrate applications of this embodiment to the first embodiment, and FIGS. 16A and 16B illustrate application of this embodiment to the fourth embodiment. In the following, description will be made regarding operations and effects of this embodiment with reference to FIGS. 15A and 15B as an example.

Pumps 10a and 10b or a pump 10c are activated to fill and circulate a heat medium in the pressure chamber 102. In this way, the heat-collecting diaphragm 101 is deformed in an expanding manner until contacting the heat-radiating plate 122 as illustrated with dashed lines in FIG. 15B. At the same time, air inside the enclosed space 110 is evacuated from evacuation port 111 by use of pumping means such as a vacuum pump.

In this way, a difference in pressure between the pressure chamber 102 and the enclosed space 110 is increased even if fluid pressure inside the pressure chamber 102 is low. Accordingly, it is possible to make close contacts between the heat-collecting diaphragm 101 and the heat-radiating plate 122. In addition, the evacuation port 111 is shut with a valve 112 when the pressure inside the enclosed space 110 decreases to a predetermined pressure, and a fluid having thermal conductivity at least higher than air is filled through a liquid inlet (not shown).

In this way, the fluid, having a higher thermal conductivity than the air, is filled into a gap remaining between the heat-collecting diaphragm 101 and the heat-radiating plate 122. Accordingly, it is possible to reduce contact thermal resistance between the heat-collecting diaphragm 101 and the heat-radiating plate 122.

It is preferred that the fluid, which has a higher thermal conductivity than the air, have a boiling point of 373.5 Kelvin (K) or higher at 1 atmosphere (atm). The fluid is preferably selected from water, ethylene glycol, glycerol, toluene, octane, chlorobenzene, lubricating oil, spindle oil, transformer oil, kerosene, silicon oil, mercury, cesium, potassium, rubidium, sodium and the like.

It should be noted that this embodiment is also applicable to a heat collector using a bellows as disclosed in the above-mentioned publication.

(Eighth Embodiment)

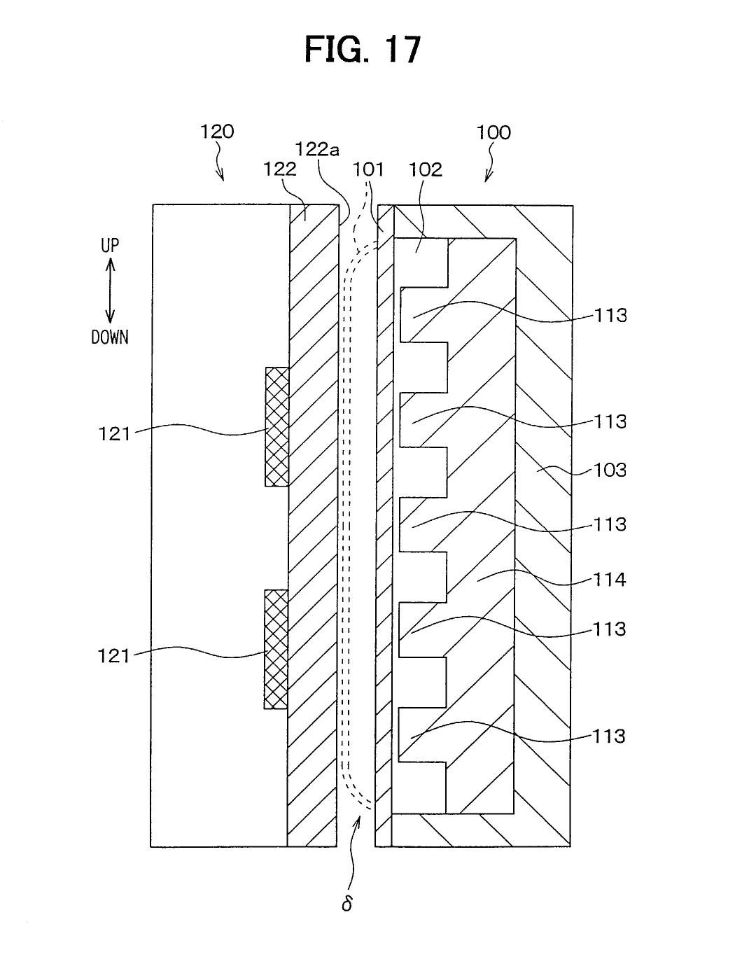

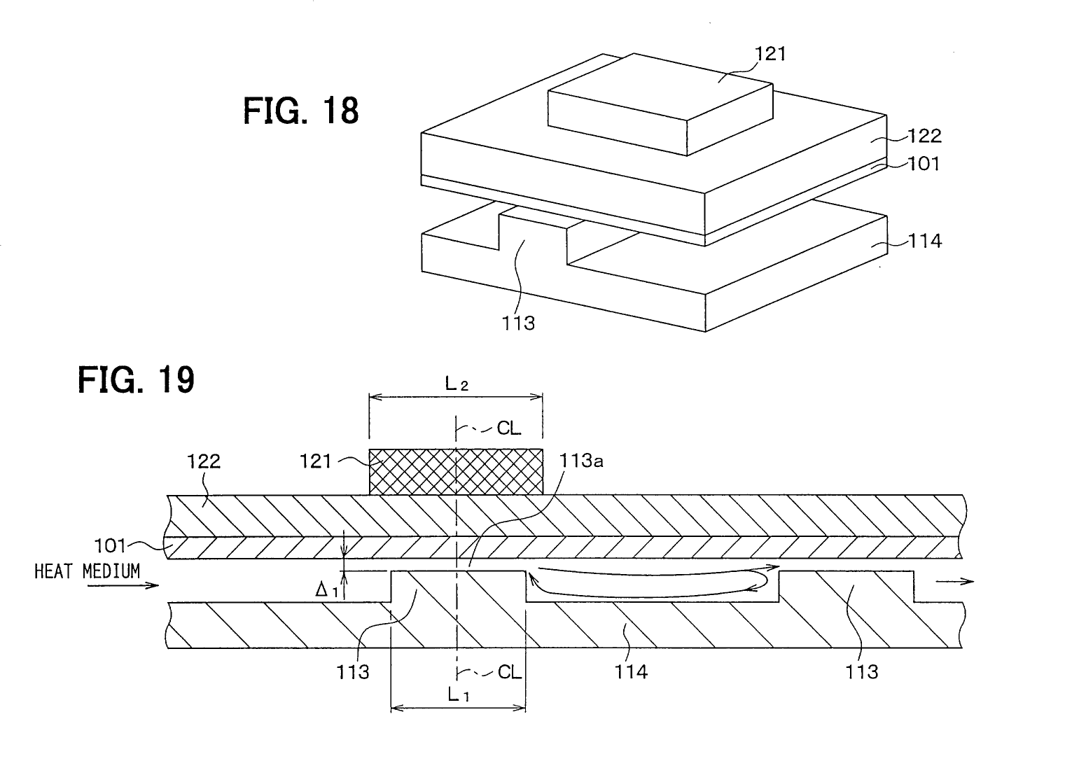

FIG. 17 is a schematic diagram showing a heat collector 100 according to this embodiment. A heat collector internal structure 114 is provided with a plurality of protrusions 113 disposed in a position of a heat collector casing 103 opposite to a radiating surface 122a with the heat-collecting diaphragm 101 interposed between the structure and the radiating surface and facing the heat-collecting diaphragm 101. FIG. 18 is a perspective view showing part of the protrusions 113.

It is preferred that the heat collector internal structure 114 and the heat collector casing 103 be made of a material having low heat conductivity such as polypropylene or phenol. However, a metallic material or appropriate resin is also acceptable.

Moreover, FIG. 19 is an enlarged view of part of the protrusions 113 and the radiating surface 122a, in which the protrusions 113, at least relevant to the number of heat-generating elements 121 out of the plurality of protrusions 113, are positioned in regions corresponding to a heat-generating instrument 120. Moreover, a gap dimension Al of a gap 113a between the heat-collecting diaphragm 101 and a tip of the protrusion 113 is set within 1 mm.

Furthermore, an outside dimension L1 in a region of the protrusion 113 approximately parallel to a circulating direction of a heat medium is set smaller than an outside dimension L2 in a region of the heat-generating element 121 approximately parallel to the circulating direction of the heat medium. In this way, the protrusion 113 functions as a turbulence promoter to disturb a flow of the heat medium which is a refrigerant, whereby thermal conductivity between the heat medium and the heat-collecting diaphragm 101 is increased. Therefore, thermal transfer from the radiating surface 122a to the heat-collecting diaphragm 101 is promoted, whereby the heat-generating element 121 can be cooled.

Moreover, since the heat-collecting diaphragm 101 in this embodiment is a thin film without provision of the fin 105 or the like, the heat-collecting diaphragm 101 is easily bent and deformed.

Therefore, the heat-collecting diaphragm 101 is adapted to the radiating surface 122a in a contacting manner when the heat-collecting diaphragm 101 is deformed and thereby contacts the radiating surface 122a upon receipt of the pressure of the heat medium. Accordingly, it is possible to decrease contact thermal resistance between the radiating surface 122a and the heat-collecting diaphragm 101. Consequently, thermal transfer from the radiating surface 122a to the heat-collecting diaphragm 101 is promoted, whereby the heat-generating element 121 can be cooled.

Since the gap dimension Δ1 is as small as 1 mm or less, it is possible to increase a flow rate of the heat medium flowing in the gap 113a. Therefore, it is possible to increase thermal conductivity between the heat-collecting diaphragm 101 and the heat medium. Accordingly, thermal transfer from the radiating surface 122a to the heat-collecting diaphragm 101 is promoted, whereby the heat-generating element 121 can be cooled.

Moreover, since the protrusion 113 is positioned in the region corresponding to the heat-generating element 121, it is possible to dissipate the heat of the heat-generating element 121 from the radiating surface 122a toward the heat-collecting diaphragm 101 more reliably.

As shown in FIG. 19, the heat medium flows toward a downstream side while passing over the protrusion 113 on an upstream side (located on the left side of the sheet), and then the heat medium collides against the protrusion 113 on the downstream side (located on the right side of the sheet). Then, part of the heat medium is reflected by the protrusion 113 and collides against the protrusion 113 on the upstream side. Further, the heat medium deflects the circulating direction thereof toward the heat-collecting diaphragm 101 and collides against the heat-collecting diaphragm 101. Such a flow of the heat medium, which collides against the protrusion 113 on the downstream side and is thereby reversed, will be hereinafter referred to as a reverse flow.

In this event, according to the embodiment, the outside dimension L1 in the region of the protrusion 113 approximately parallel to the circulating direction of the heat medium is set smaller than the outside dimension L2 in the region of the heat-generating element 121 approximately parallel to the circulating direction of the heat medium. Therefore, it is possible to allow the reverse flow to collide against the heat-collecting diaphragm 101 in a region corresponding to the heat-generating element 121. In this way, the heat from the heat-generating element 121 can be dissipated from the radiating surface 122a toward the heat-collecting diaphragm 101.

(Ninth Embodiment)

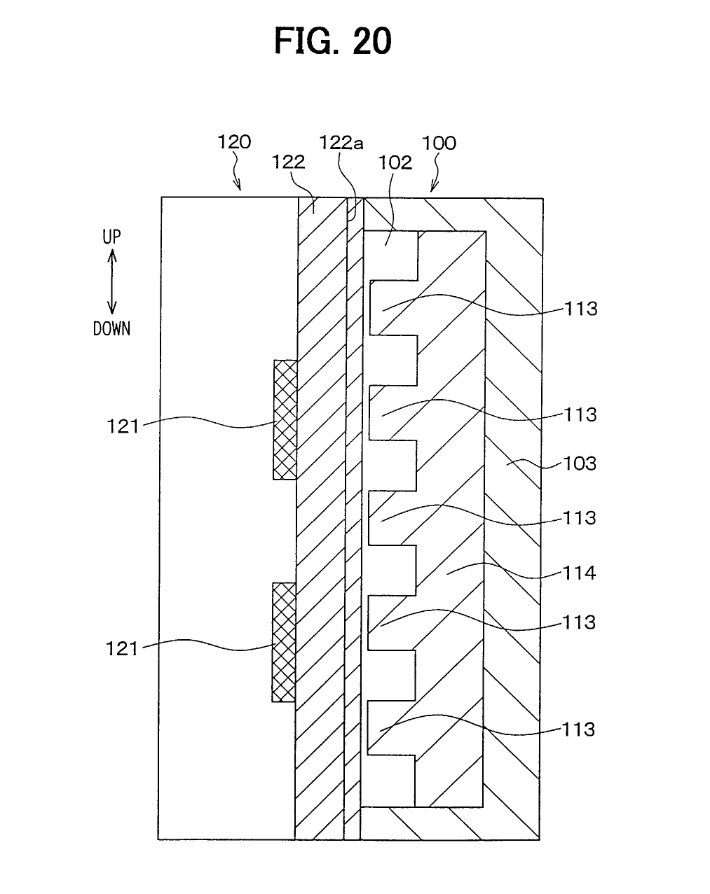

This embodiment is a modified example of the eighth embodiment. In this embodiment, as shown in FIG. 20, a heat-generating instrument 120 and a heat collector 100 are disposed such that a radiating surface 122a and a heat-collecting diaphragm 101 contact each other prior to activating pumps 10a and 10b to fill and circulate a heat medium in a pressure chamber 102.

Next, description will be made regarding operations and effects of this embodiment. As in the previous embodiment, if a gap δ (see FIG. 17) is provided between the radiating surface 122a and the heat-collecting diaphragm 101 prior to filling and circulating the heat medium in the pressure chamber 102, such a gap δ may fluctuate substantially due to variation in disposition of the heat-generating instrument 120 and the heat collector 100.

In a case where the gap δ is increased, contact pressure between the radiating surface 122a and the heat-collecting diaphragm 101 is decreased, whereby contact thermal resistance between both items 122a and 101 is increased. Consequently, thermal transfer from the radiating surface 122a to the heat-collecting diaphragm 101 is inhibited. Accordingly, if the gap δ (see FIG. 17) is provided between the radiating surface 122a and the heat-collecting diaphragm 101 prior to filling and circulating the heat medium in the pressure chamber 102 as in the previous embodiment, location setting of the heat-generating instrument 120 and the heat collector 100 needs to be accurately controlled.

On the contrary, in this embodiment, the heat-generating element 120 and the heat collector 100 are disposed such that the radiating surface 122a and the heat-collecting diaphragm 101 contact with each other prior to activating the pumps 10a and 10b to fill and circulate the heat medium in the pressure chamber 102. Accordingly, if the pressure inside the pressure chamber 102 is reduced, it is possible to prevent the contact pressure between the radiating surface 122a and the heat-collecting diaphragm 101 from falling from a predetermined pressure value, and to prevent substantial fluctuation of the contact pressure.

Therefore, it is possible to simplify pressure resistance structures of the heat collector 100 and the heat-generating instrument 120 and to adopt the pumps 10a and 10b having relatively small ejection pressures. Accordingly, the heat-generating instrument 120 can be stably cooled while reducing the manufacturing costs of the heat generator 100.

(Tenth Embodiment)

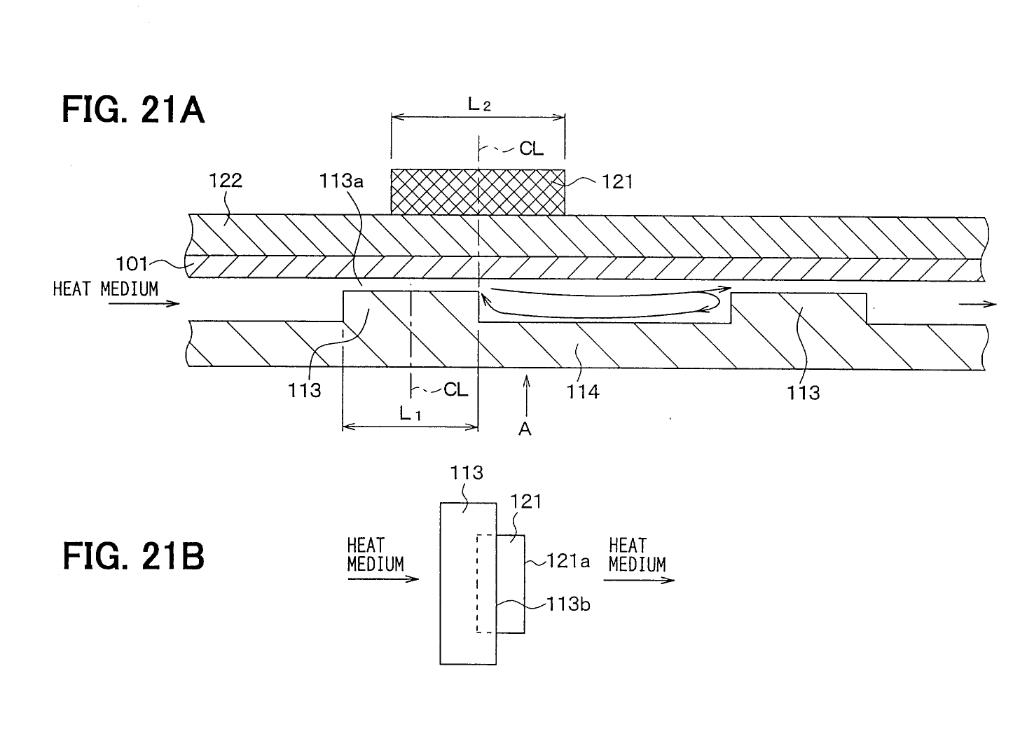

In the eighth and the ninth embodiments, a centerline CL of the protrusion 113 and a centerline CL of the heat-generating element 121 are almost aligned (see FIG. 19). However, in this embodiment, as shown in FIG. 21, a centerline CL of a heat-generating element 121 is shifted toward a downstream side of a heat medium with respect to a centerline CL of a protrusion 113, such that an end portion 121a on the downstream side of the heat medium of the heat-generating element 121 is positioned on a more downstream side of the heat medium than an end portion 113b on the downstream side of the heat medium of the protrusion 113 when viewed from the protrusion 113 side, that is, when the protrusion 113 and the heat-generating element 121 are projected on a hypothetical plane S parallel to a flow of the heat medium (see FIG. 21B in particular).

In this way, it is possible to allow a reverse flow to collide against a region of a heat-collecting diaphragm 101 corresponding to the heat-generating element 121. Accordingly, heat of the heat-generating element 121 can be dissipated from a radiating surface 122a toward the heat-collecting diaphragm 101.

(Eleventh Embodiment)

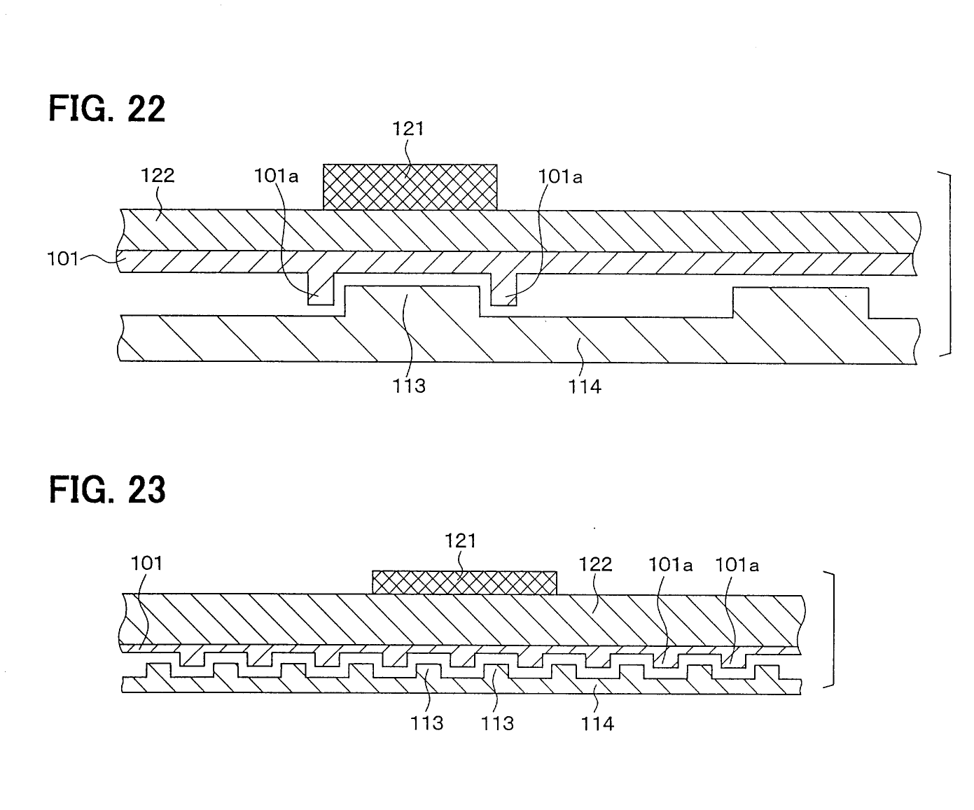

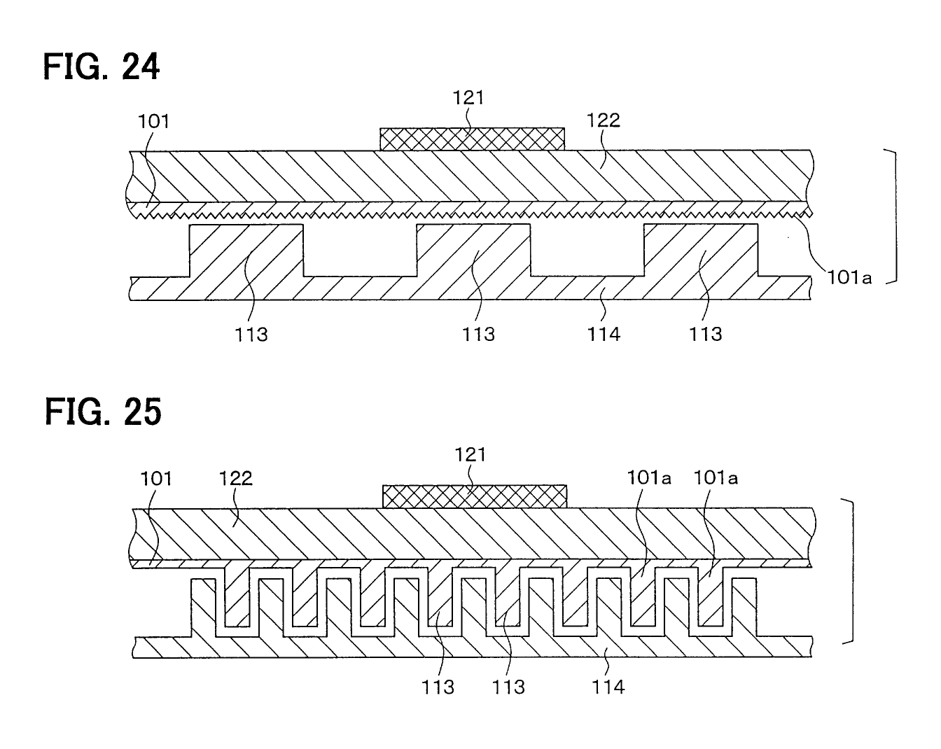

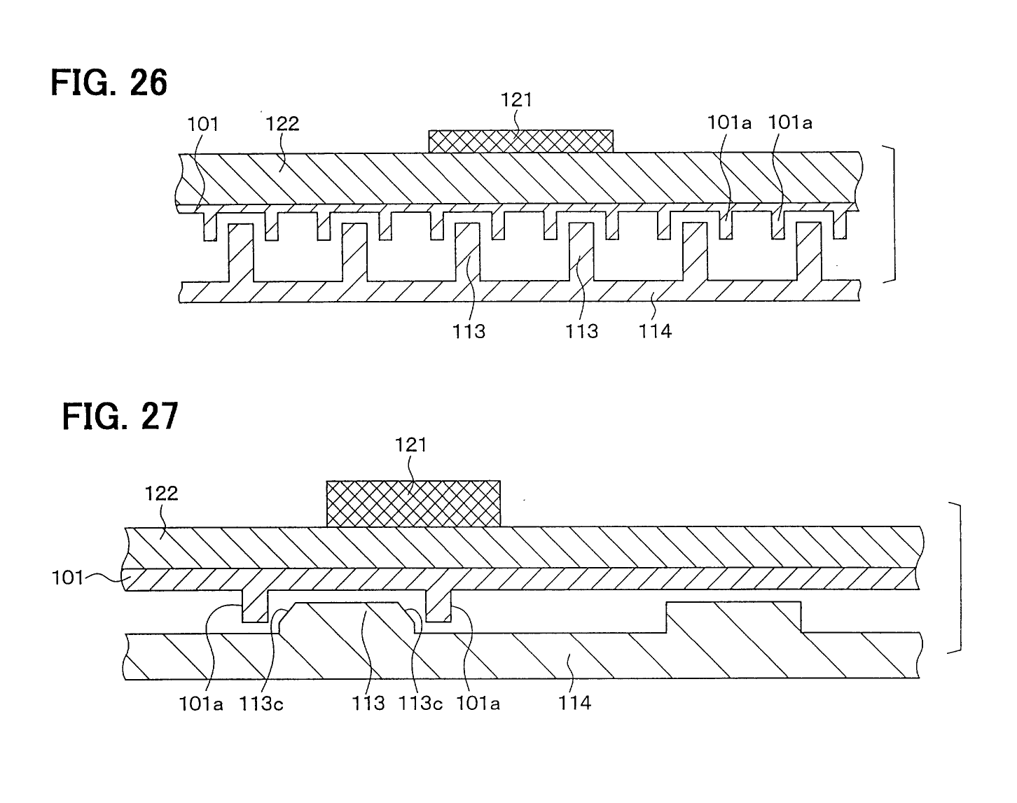

In this embodiment, as shown in FIGS. 22 to 27, a plurality of protrusions 101a are provided on a heat-collecting diaphragm 101 on a side contacting with a heat medium. Because of this, a flow of the heat medium is more disturbed and a heat-transferring area between the heat medium and the heat-collecting diaphragm 101 is thereby increased. Accordingly, thermal transfer from a radiating surface 122a toward the heat-collecting diaphragm 101 is promoted, whereby a heat-generating element 121 can be cooled.

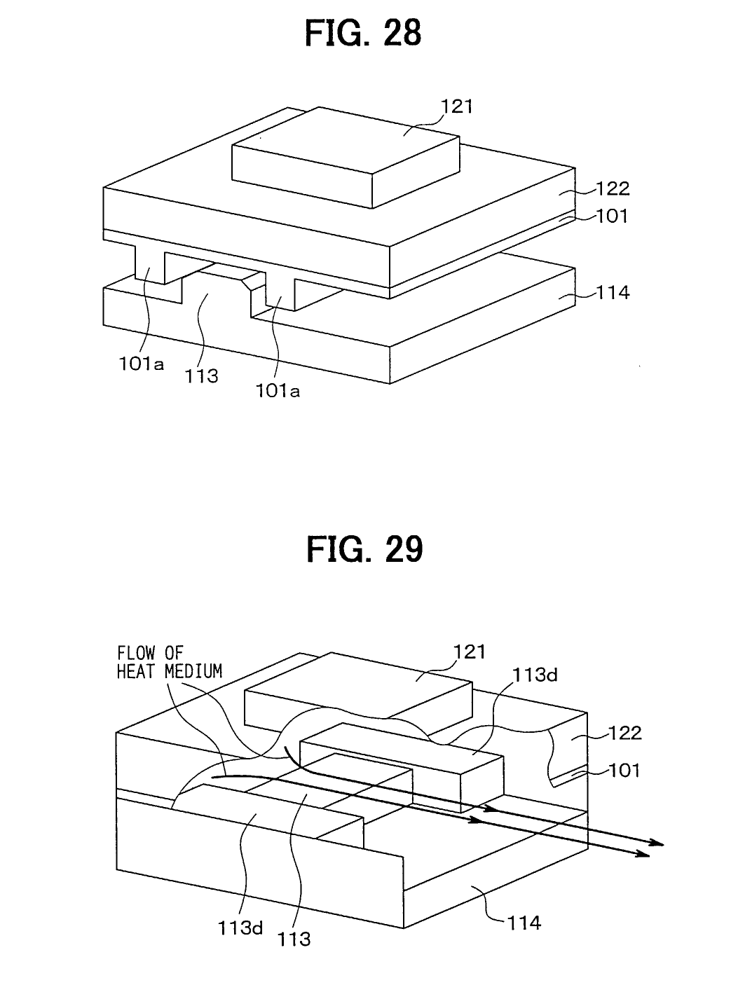

In particular, according to an example shown in FIG. 27, corner portions 113c in a circulating direction of the heat medium of the protrusion 113 are rounded or chamfered and occurrence of swirls, which may induce pressure losses on a downstream side of the protrusion 113, are thereby prevented so as to reduce the pressure losses of the heat medium inside a pressure chamber 102. Incidentally, FIG. 28 is a perspective view of FIG. 27.

(Twelfth Embodiment)

In the eighth to the tenth embodiments, the flow rate of the heat medium is increased by means of reducing the size of the gap 113a. However, in this embodiment, second protrusions 113d are provided as shown in FIG. 29 to narrow a passage for a heat medium, so that the heat medium flows intensively in a region corresponding to a heat-generating element 121. In this way, the heat-generating element 121 can be cooled.

(Other Embodiments)

It should be noted that the heat-generating elements 121 are not limited to those described in the foregoing embodiments. For example, various electric instruments such as rectifiers, transformers, electric converters, electric apparatuses, electronic apparatuses, radio amplifiers, radio transmitters, inverters, power modules, capacitors, heaters, fuel batteries, semiconductors and batteries are conceivable.

Moreover, the heat media are not limited to those described in the foregoing embodiments. For example, natural refrigerants such as water or ammonia, fluorocarbon type refrigerants such as Fluorinert, chlorofluorocarbon type refrigerants such as HCFC123 or HFC134a, alcoholic refrigerants such as methanol or ethanol, and ketone type refrigerants such as acetone are conceivable.

Furthermore, the present invention has been described with reference to the foregoing embodiments using a cellular phone base station as an example. However, the present invention is not limited thereto. For example, the present invention is also applicable to cooling various types of heat-generating elements (such as gas turbine engines, gas engines, diesel engines, gasoline engines, fuel batteries, electronic apparatuses, electric apparatuses, electric converters and storage cells) which are disposed in spaces of buildings, basements, factories, warehouses, houses, garages and vehicles.

Moreover, in the foregoing embodiments, one heat collector 100 is provided to multiple (two pieces, for example) heat-generating elements 121. However, the present invention is not limited thereto. If the heat collectors 100 are provided in the number corresponding to the plural heat-generating elements 121, then it is sufficient to detach only one heat collector 100 for each heat-generating element 121 subject to repair or replacement. Therefore, workability of repairing or replacing can be enhanced.

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A heat collector (100) for collecting heat of a heat-generating instrument (120), the heat collector (100) comprising:
a heat-collecting diaphragm (101) for being deformed upon receipt of fluid pressure to contact a radiating surface (122a) of the heat-generating instrument (120);
a heat collector casing (103) fixing the heat-collecting diaphragm (101) thereon for defining a pressure chamber (102) to apply the fluid pressure to the heat-collecting diaphragm (101); and
a valve device (104) provided on a fluid inlet side of the pressure chamber (102) for opening and closing a fluid passage.

2. The heat collector according to claim 1, wherein the valve device (104) closes the fluid passage when a heat value of the heat-generating instrument (120) falls from a predetermined value.

3. The heat collector according to claim 1, wherein the valve device (104) closes the fluid passage when the fluid pressure falls from a predetermined pressure value.

4. The heat collector according to claim 2, wherein the valve device (104) closes the fluid passage when the fluid pressure falls from a predetermined pressure value.

5. The heat collector according to claim 1, wherein the valve device (104) closes the fluid passage when an electric signal of the heat-generating instrument (120) is not present.

6. The heat collector according to claim 4, wherein the valve device (104) closes the fluid passage when an electric signal of the heat-generating instrument (120) is not present.

7. The heat collector according to claim 1, wherein a pump device (10a, 10b) for supplying fluid to the pressure chamber (102) stops operating when a pressure inside the pressure chamber (102) falls from a predetermined pressure value.

8. The heat collector according to claim 6, wherein a pump device (10a, 10b) for supplying the fluid to the pressure chamber (102) stops operating when a pressure inside the pressure chamber (102) falls from a predetermined pressure value.

9. The heat collector according to claim 1, wherein the pump device (10a, 10b) for supplying fluid to the pressure chamber (102) stops operating when a heat value of the heat-generating instrument (120) falls from a predetermined value.

10. The heat collector according to claim 8, wherein the pump device (10a, 10b) for supplying the fluid to the pressure chamber (102) stops operating when a heat value of the heat-generating instrument (120) falls from a predetermined value.

11. The heat collector according to claim 1, wherein the pump device (10a, 10b) for supplying the fluid to the pressure chamber (102) stops operating when an electric signal of the heat-generating instrument (120) is not present.

12. The heat collector according to claim 10, wherein the pump device (10a, 10b) for supplying the fluid to the pressure chamber (102) stops operating when an electric signal of the heat-generating instrument (120) is not present.

13. A heat collector (100) for collecting heat dissipated by a heat-generating instrument (120), the heat collector (100) comprising:
a heat-radiating diaphragm (108) defining a pressure chamber (107) of which an inner pressure varies upon receipt of heat from the heat-generating instrument (120) and for being deformed in accordance with the pressure inside the pressure chamber (107); and
a heat-collecting plate (109) for contacting with the heat-radiating diaphragm (108) when the heat-radiating diaphragm (108) is deformed by an increase in the pressure inside the pressure chamber (107).

14. The heat collector according to claim 13, further comprising:
a valve device (104) for opening and closing a fluid passage to effectuate circulation of fluid for retrieving the heat collected on the heat-collecting plate (109).

15. The heat collector according to claim 13, wherein the valve device (104) closes the fluid passage when fluid pressure falls from a predetermined pressure value.

16. The heat collector according to claim 14, wherein the valve device (104) closes the fluid passage when fluid pressure falls from a predetermined pressure value.

17. The heat collector according to claim 13, further comprising:
a pump device (10a, 10b) for circulating fluid to retrieve the heat collected on the heat-collecting plate (109),
wherein the pump device (10a, 10b) stops operating when fluid pressure falls from a predetermined pressure value.

18. The heat collector according to claim 16, further comprising:
a pump device (10a, 10b) for circulating fluid to retrieve the heat collected on the heat-collecting plate (109),
wherein the pump device (10a, 10b) stops operating when fluid pressure falls from a predetermined pressure value.

19. The heat collector according to claim 13, further comprising:
a pump device (10a, 10b) for circulating fluid to retrieve the heat collected on the heat-collecting plate (109),
wherein the pump device (10a, 10b) stops operating when a heat value of the heat-generating instrument (120) falls from a predetermined value.

20. The heat collector according to claim 18, further comprising:
a pump device (10a, 10b) for circulating fluid to retrieve the heat collected on the heat-collecting plate (109),
wherein the pump device (10a, 10b) stops operating when a heat value of the heat-generating instrument (120) falls from a predetermined value.

21. A heat collector for collecting heat of a heat-generating instrument (120) by allowing a diaphragm (101, 108) to deform in accordance with a pressure so that the diaphragm (101, 108) can contact a heat-transferring surface (122a, 109),
wherein an enclosed space (110) is defined exterior to the diaphragm (101, 108), and the heat-transferring surface (122a, 109) and the diaphragm (101, 108) are allowed to contact each other by reducing a pressure inside the enclosed space (110).

22. The heat collector according to claim 21, wherein fluid having a thermal conductivity greater than air fills the enclosed space (110) after the pressure inside the enclosed space (110) is lowered.

23. A cooling system for cooling a heat-generating instrument (120) composed of a plurality of heat-generating elements (121), the cooling system comprising:
a plurality of heat collectors (100) equal in number to the plurality of heat-generating elements (121) for collecting heat from the heat-generating elements (121); and
cooling means (4) for cooling the heat collectors (100) by retrieving the heat collected therein.

24. The cooling system according to claim 23, further comprising:
a base member (106) provided with positioning means (131, 132) for positioning the heat-generating instrument (120) and the heat collector (100).

25. A heat collector (100) for collecting heat of a heat-generating instrument (120), the heat collector (100) comprising:
a heat-collecting diaphragm (101) for contacting a radiating surface (122a) of the heat-generating instrument (120) upon receipt of fluid pressure; and
a heat collector internal structure (114) including a protrusion (113), both being disposed opposite to the heat-collecting diaphragm (101) in a position opposite to the radiating surface (122a) with the heat-collecting diaphragm (101) interposed between the structure (114) and the radiating surface (122a).

26. The heat collector according to claim 25, wherein the heat-collecting diaphragm (101) is formed of a thin film.

27. The heat collector according to claim 25, wherein the heat-collecting diaphragm (101) and a tip of the protrusion (113) defines a gap dimension (Δ1) between them, set less than or equal to 1 mm.

28. The heat collector according to claim 26, wherein the heat-collecting diaphragm (101) and a tip of the protrusion (113) defines a gap dimension (Δ1) between them, set less than or equal to 1 mm.

29. The heat collector according to claim 25,
wherein the protrusions (113) are provided at given intervals in a circulating direction of the fluid, and
an outside dimension (L1) in a region of the protrusion (113) being approximately parallel to the circulating direction of the fluid is smaller than an outside dimension (L2) in a region of the heat-generating element (121) which is approximately parallel to the circulating direction of the fluid.

30. The heat collector according to claim 28,
wherein the protrusions (113) are provided at given intervals in a circulating direction of the fluid, and
an outside dimension (L1) in a region of the protrusion (113) being approximately parallel to the circulating direction of the fluid is smaller than an outside dimension (L2) in a region of the heat-generating element (121) which is approximately parallel to the circulating direction of the fluid.

31. The heat collector according to claim 25, wherein an end portion (121a) of the heat-generating element (121) on a downstream side of a fluid flow is located at a more downstream side than an end portion (113b) of the protrusion (113) on the downstream side of the fluid flow when the protrusion (113) and the heat-generating element (121) are viewed from the protrusion (113) side.

32. The heat collector according to claim 30, wherein an end portion (121a) of the heat-generating element (121) on a downstream side of a fluid flow is located at a more downstream side than an end portion (113b) of the protrusion (113) on the downstream side of the fluid flow when the protrusion (113) and the heat-generating element (121) are viewed from the protrusion (113) side.

33. A cooling system for cooling a heat-generating instrument (120) composed of a plurality of heat-generating elements (121), the cooling system comprising:
a plurality of heat collectors (100) equal in number to the plurality of heat-generating elements (121) for collecting heat from the heat-generating elements (121); and
a refrigerator (4) for cooling the heat collectors (100) by retrieving the heat collected therein, wherein said refrigerator (4) further comprises:
a first pair of heat exchangers (6) and a second pair of heat exchangers (7), wherein the heat exchangers (6, 7) exchange a fluid using a plurality of pumps (9a-9e); and
a first radiator (8a) and a second radiator (8b), wherein the radiators (8a, 8b) contain the fluid acquired from the heat exchangers (6, 7) and exhaust heat using a fan (8c).

34. A cooling system for cooling according to claim 33, wherein the heat exchangers (6, 7) and the pumps (9a-9e) are located inside a device and the radiators (8a, 8b) are located outside the device.
